(19) United States
(12) Patent Application Publication
(10) Pub. No.: US 2025/0208471 A1
(43) Pub. Date: Jun. 26, 2025

(54) ARRAY SUBSTRATE, DISPLAY PANEL, AND DISPLAY DEVICE

(71) Applicants: Hefei BOE Optoelectronics Technology Co., Ltd, Hefei (CN); BOE TECHNOLOGY GROUP CO., LTD, Beijing (CN)

(72) Inventors: Zhaofan LIU, Beijing (CN); Xianxue DUAN, Beijing (CN); Zhihai ZHANG, Beijing (CN)

(73) Assignees: Hefei BOE Optoelectronics Technology Co., Ltd, Heifei, AH (CN); BOE TECHNOLOGY GROUP CO., LTD, Beijing (CN)

(21) Appl. No.: 18/728,819

(22) PCT Filed: May 27, 2022
(86) PCT No.: PCT/CN2022/095723

§ 371 Date: Jan. 15, 2025

(51) Int. Cl. G02F 1/1362; G02F 1/1339; H10D 86/40

(52) U.S. Cl. CPC G02F 1/136286; G02F 1/1339; G02F 1/136222; G02F 1/136227; H10D 86/441

(57) ABSTRACT

An array substrate, a display panel, and a display device are provided. The array substrate includes: a first base substrate, an insulating layer group and a reflective layer group. The insulating layer group is arranged at a side of the first base substrate, and a surface of the insulating layer group away from the first base substrate is provided with a first protruding portion. The reflective layer group is arranged at a side of the insulating layer group away from the first base substrate. The reflective layer group includes a plurality of reflective portions, a first gap is provided between two adjacent reflective portions, and the first protruding portion is arranged in the first gap.

### CROSS REFERENCE TO RELATED APPLICATION

The present application is the U.S. National Stage of International Application No. PCT/CN2022/095723, filed on May 27, 2022, the contents of which are incorporated herein by reference in their entireties for all purposes.

### TECHNICAL FIELD

The present disclosure relates to the display technical field, and in particular, to an array substrate, a display panel and a display device.

### BACKGROUND

Reflection type Liquid Crystal Display (RLCD) is widely used in e-books, outdoor advertisements or other products due to its thinness, energy saving, eye protection and other advantages.

However, current reflection liquid crystal displays are prone to defects such as bright spots.

It should be noted that the information disclosed in the background section is only for enhancing the understanding of the background of the present disclosure, and therefore may include information that does not constitute prior art known to those of ordinary skill in the art.

### SUMMARY

The purpose of the present disclosure is to overcome the shortcomings of the above-mentioned related art, and provide an array substrate, a display panel and a display device.

According to an aspect of the present disclosure, there is provided an array substrate, comprising:
a first base substrate;
an insulating layer group arranged at a side of the first base substrate, wherein a surface of the insulating layer group away from the first base substrate is provided with a first protruding portion; and
a reflective layer group arranged at a side of the insulating layer group away from the first base substrate, wherein the reflective layer group comprises a plurality of reflective portions, a first gap is provided between two adjacent reflective portions, and the first protruding portion is arranged in the first gap.

In an example embodiment, a part of the first protruding portion extends to a side of the reflective layer group close to the first base substrate to make a width of the first gap less than or equal to a width of the first protruding portion.

In an example embodiment of the present disclosure, the first protruding portion comprises:
a plurality of first protruding strips extending along a first direction;
a plurality of second protruding strips extending along a second direction, wherein the plurality of first protruding strips are connected with the plurality of second protruding strips to form a plurality of grids;
wherein first gap comprises:
a plurality of first sub-gaps extending along the first direction, wherein the first protruding strips are arranged in the first sub-gaps; and
a plurality of second sub-gaps extending along the second direction, wherein the second protruding strips are arranged in the second sub-gaps, and the plurality of first sub-gaps are connected with the plurality of second sub-gaps to form a plurality of grids;
wherein the first direction and the second direction are parallel to a surface of the first base substrate close to the insulating layer group, and the first direction intersects the second direction.

In an example embodiment of the present disclosure, the first protruding strips at least comprise a first part and a second part, and a width of the first part in the second direction is different from a width of the second part in the second direction;
wherein the second protruding strips at least include a third part and a fourth part, and a width of the third part in the first direction is different from a width of the fourth part in the first direction.

In an example embodiment of the present disclosure, the array substrate further includes:
a switch layer group arranged between the first base substrate and the insulating layer group, wherein the switch layer group includes a plurality of switch units, a second gap is provided between two adjacent switch units, and an orthographic projection of the first protruding portion on the first base substrate is located within an orthographic projection of the second gap on the first base substrate.

In an example embodiment of the present disclosure, the switch layer group further includes:
a plurality of gate lines extending along the first direction, wherein the gate line is correspondingly located between two adjacent switch units, and orthographic projections of the first protruding strips on the first base substrate overlap with orthographic projections of the gate lines on the first base substrate; and
a plurality of data lines extending along the second direction, wherein the data line is correspondingly located between two adjacent switch units, and orthographic projections of the second protruding strips on the first base substrate overlap with orthographic projections of the data lines on the first base substrate.

In an example embodiment of the present disclosure, the first protruding strips have a width in the second direction greater than or equal to that of the gate lines in the second direction, and the second protruding strips have a width in the first direction greater than or equal to that of the data lines in the first direction.

In an example embodiment of the present disclosure, the switch layer group further includes:
a gate layer arranged at a side of the first base substrate;
a gate insulating layer arranged at a side of the gate layer away from the first base substrate;
an active layer arranged at a side of the gate insulating layer away from the first base substrate; and
a source-drain layer arranged at a side of the active layer away from the first base substrate.

In an example embodiment of the present disclosure, the gate layer includes:
a plurality of gate lines extending along the first direction;
a plurality of second sub-electrodes arranged in an array at a side of the first base substrate; and
a plurality of connection portions, wherein the connection portion is connected between two adjacent second sub-electrodes which are arranged along the first direction.

In an example embodiment of the present disclosure, a third gap is provided between one of second sub-electrodes and one of the gate lines, the one of second sub-electrodes and the one of the gate lines belong to different adjacent pixels, and an orthographic projection of the first protruding strip on the first base substrate overlaps with an orthographic projection of the third gap on the first base substrate, and the first protruding strip has a width in the second direction smaller than a width of the third gap in the second direction.

In an example embodiment of the present disclosure, the active layer includes:
a channel portion arranged at a side of the gate lines away from the first base substrate; and
a filling portion spaced apart from the channel portion, located at a side of the connection portions away from the first base substrate, and covering at least part of sidewalls of the connection portions.

In an example embodiment of the present disclosure, the source-drain layer includes:
a plurality of data lines extending along the second direction, wherein a part of the data lines are located at a side of the filling portion away from the connection portions;
a plurality of light-shielding portions arranged in an array, wherein orthographic projections of the light-shielding portions on the first base substrate are located within orthographic projections of the second sub-electrodes on the first base substrate;
a source electrode, wherein one end of the source electrode is connected to the data line; and
a drain electrode, wherein one end of the drain electrode is connected to the light-shielding portion.

In an example embodiment of the present disclosure, the data line includes:
a plurality of first segments extending along the first direction;
a plurality of second segments extending along the second direction and connected to a part of the first segments, wherein one of the second segments is connected to ends of two adjacent first segments; and
a plurality of third segments extending along the second direction and connected to the another part of the first segments, wherein one of the third segments is connected to other ends of two adjacent first segments, and the second segments and the third segments are arranged alternately;
wherein one of the third segments is located between two adjacent light-shielding portions, and is at different distances from the two adjacent light-shielding portions, and one of the second sections is connected to two pixels which are adjacent in the second direction.

In an example embodiment of the present disclosure, a width of a fifth gap between the one of the third segments and a first light-shielding portion is larger than a width of a fourth gap between the one of the third segments and a second light-shielding portion, the first light-shielding portion and the one of the third segments belong to a same pixel, and the second light-shielding portion and the one of the third segments belong to different adjacent pixels.

In an example embodiment of the present disclosure, the orthographic projection of the second protruding strip on the base substrate overlaps with an orthographic projection of the fifth gap on the base substrate, and a width of the second protruding strip in the first direction smaller than a width of the fifth gap in the first direction.

In an example embodiment of the present disclosure, a first via hole is provided in the insulating layer group, and the array substrate further includes:
a first electrode layer arranged between the insulating layer group and the reflective layer, wherein the first electrode layer includes a plurality of first electrodes, and the first electrode is connected with the source-drain layer through the first via hole.

In an example embodiment of the present disclosure, orthographic projections of the first electrodes on the first base substrate overlap with orthographic projections of the reflective portions on the first base substrate.

In an example embodiment of the present disclosure, the reflective layer group includes:
a first ITO layer arranged at a side of the insulating layer group away from the first base substrate;
a silver metal layer arranged at a side of the first ITO layer away from the first base substrate; and
a second ITO layer arranged at a side of the silver metal layer away from the first base substrate.

In an example embodiment of the present disclosure, a height of a surface of the first protruding portion away from the first base substrate in a third direction is higher than a height of a surface of the reflective layer group away from the first base substrate in the third direction, and the third direction is perpendicular to a surface of the first base substrate close to the insulating layer group.

In an example embodiment of the present disclosure, a plurality of second protruding portions are provided at a surface of the insulating layer group away from the first base substrate, a plurality of third protruding portions are provided at a surface of the reflective layer group away from the first base substrate, and orthographic projections of the second protruding portions on the first base substrate are located within orthographic projections of the third protruding portions on the first base substrate.

In an example embodiment of the present disclosure, a height of the second protruding portions is the same as a height of the first protruding portion.

In an example embodiment of the present disclosure, the insulating layer group includes:
a first protective layer arranged at a side of the first base substrate; and
an insulating layer arranged at a side of the first protective layer away from the first base substrate.

In an example embodiment of the present disclosure, the first protruding portion and the second protruding portions are provided at the insulating layer.

In an example embodiment of the present disclosure, the insulating layer group further includes:
a second protective layer arranged at a side of the insulating layer away from the first base substrate, a fourth protruding portion and a plurality of fifth protruding portions are arranged at the insulating layer, and the first protruding portion corresponding to the fourth protruding portion and the second protruding portions corresponding to the fifth protruding portions are provided at the second protective layer.

According to another aspect of the present disclosure, there is provided a display panel, including:
an array substrate which is the array substrate according to any one of the above embodiments;
a color filter substrate arranged at a side of the array substrate close to the reflective layer group;
a sealant frame arranged between the array substrate and the color filter substrate; and
a liquid crystal layer arranged between the array substrate and the color filter substrate and located in the sealant frame.

In an example embodiment of the present disclosure, the display panel further includes:
a diffusion film arranged at a side of the color filter substrate away from the array substrate.

According to another aspect of the present disclosure, there is provided a display device, including the display panel according to any one of the above embodiments.

It is to be understood that both the foregoing general description and the following detailed description are exemplary and explanatory only and are not restrictive of the present disclosure.

### BRIEF DESCRIPTION OF THE DRAWINGS

The accompanying drawings, which are incorporated in and constitute a part of the specification, illustrate embodiments consistent with the present disclosure and together with the specification serve to explain the principles of the present disclosure. Apparently, the drawings in the following description are only some embodiments of the present disclosure, and those skilled in the art may obtain other drawings according to these drawings without creative efforts.

FIG. 1 is a schematic structural diagram of a display panel in the related art.

FIG. 2 is a schematic diagram of a display effect of the display panel in FIG. 1.

FIG. 3 is a schematic diagram of a display effect of a display panel according to an embodiment of the present disclosure.

FIG. 4 is a schematic structural diagram of an array substrate according to an example implementation of the present disclosure.

FIG. 5 is a schematic top view of a gate layer in FIG. 4.

FIG. 6 is a schematic structural view after an active layer is formed on the basis of FIG. 5.

FIG. 7 is a schematic structural view after a source-drain layer is formed on the basis of FIG. 6.

FIG. 8 is a schematic cross-sectional view cut along A-A in FIG. 7.

FIG. 9 is a schematic structural view after an insulating layer group is formed on the basis of FIG. 6.

FIG. 10 is a schematic view of a partial structure of the insulating layer group in FIG. 9.

FIG. 11 is a schematic cross-sectional view cut along B-B in FIG. 21.

FIG. 12 is a schematic cross-sectional view cut along C-C in FIG. 21.

FIG. 13 is a schematic diagram of a display effect when first protruding portions 34 are set as regular.

FIG. 14 is a schematic diagram of a display effect of a case where a part of first protruding portions 34 are set as regular and another part of first protruding portions 34 are set as irregular.

FIG. 15 is a schematic diagram of a display effect when first protruding portions 34 are set as irregular.

FIG. 16 is a schematic cross-sectional view of an array substrate after being cut along a second direction according to another example implementation of the present disclosure.

FIG. 17 is a schematic cross-sectional view of an array substrate after being cut along a first direction according to another example implementation of the present disclosure.

FIG. 18 is a schematic cross-sectional view of another example implementation cut along B-B in FIG. 21.

FIG. 19 is a schematic cross-sectional view of an array substrate after being cut along a second direction according to another example implementation of the present disclosure.

FIG. 20 is a schematic cross-sectional view of an array substrate after being cut along a first direction according to another example implementation of the present disclosure.

FIG. 21 is a schematic structural view after a reflective layer group is formed on the basis of FIG. 9.

FIG. 22 is a comparison chart of reflectivity curves under various conditions.

FIG. 23 is a schematic structural view of a display panel of the present disclosure according to an example implementation of the present disclosure.

FIG. 24 is a schematic structural view of a frame position of a display panel according to an example implementation of the present disclosure.

### EXPLANATION OF REFERENCE SIGNS

100: array substrate; 200: color filter substrate;
1: first base substrate;
2: switch layer group; 21: switch unit; 22, second gap; 23: gate layer; 231: gate line; 232: second sub-electrode; 233: connection portion; 234, third gap; 235: gate electrode; 236: sixth gap; 24: gate insulating layer; 25: active layer; 251: filling portion; 252: channel portion; 26: source-drain layer; 261: data line; 2611: first segment; 2612: second segment; 2613: third segment; 262: source electrode; 263: drain electrode; 264: light-shading portion; 265: fourth gap; 266: fifth gap; 267: connection block;
3: insulating layer group; 31: first protective layer; 311: first sub-via hole;
32: insulating layer; 321: second sub-via hole; 322: fourth protruding portion; 3221: third protruding strip; 3222: fourth protruding strip; 323: fifth protruding portion;
33: second protective layer; 331: third sub-via hole;
34: first protruding portion; 341: first protruding strip; 3411: first part; 3412: second part; 342: second protruding strip; 3421: third part; 3422: fourth part;
35: first via hole; 36: first flat surface; 37: second protruding portion;
4: first electrode layer; 41: first electrode; 42: seventh gap; 43: sixth protruding portion;
5: reflective layer group; 51: first gap; 511: first sub-gap; 512: second sub-gap; 52: reflective portion; 53: third protruding portion; 54: first ITO layer; 55: silver metal layer; 56: second ITO layer;
6: spacer; 71: first alignment film; 72: second alignment film;
201: second base substrate; 202: light-transmitting portion; 203: light-blocking portion;
301: sealant frame; 302: liquid crystal layer; 303: diffusion film;
X: first direction; Y: second direction; Z: third direction.

### DETAILED DESCRIPTION

Example implementations will now be described more fully with reference to the accompanying drawings. Example implementations may, however, be embodied in many forms and should not be construed as being limited to the implementations set forth herein; rather, these implementations are provided so that the present disclosure will be thorough and complete, and will fully convey the concept of example implementations to those skilled in the art. The same reference numerals in the drawings denote the same or similar structures, and thus their repeated descriptions will be omitted. Furthermore, the drawings are merely schematic illustrations of the present disclosure and are not necessarily drawn to scale.

Although relative terms such as “upper” and “lower” are used in this specification to describe a relative relationship of one component in a drawing to another component, these terms are used in this specification only for convenience. For example, these relative terms are based on directions in examples in the drawings. It will be understood that if a device shown in a drawing is turned upside down, a component described as “upper” would become a component as “lower”. When a structure is “on” another structure, it may mean that the structure is integrally formed on another structure, or that the structure is “directly” placed on another structure, or that the structure is “indirectly” placed on another structure through other structure(s).

The terms “one”, “a/an”, “the”, “said” and “at least one” are used to indicate the presence of one or more elements/components/etc.; the terms “comprising/comprises/comprise” and “having/has/have” are used to indicate an open-ended inclusive, and means that there may be additional elements/components/etc. in addition to the listed elements/components/etc. The words “first”, “second” and “third” are used as markers only, but are not used to limit the number of objects.

In the present disclosure, unless otherwise specified and limited, the term “connection” should be understood in a broad sense, for example, “connection” may be a fixed connection, a detachable connection, or an integral body; a direction may be a direct connection, or may be an indirect connection through an intermediary.

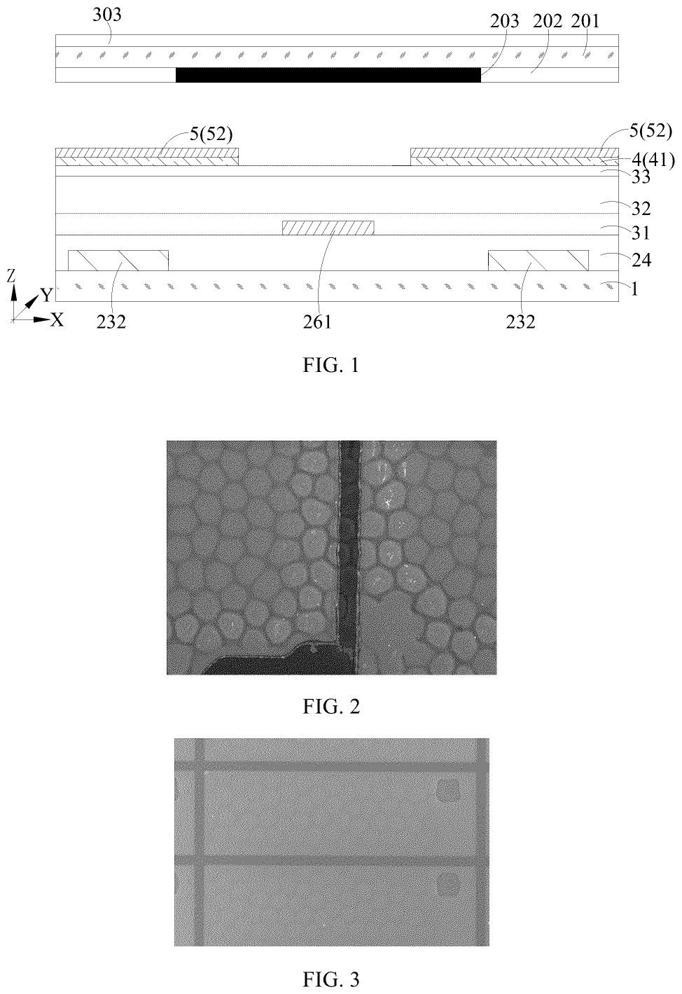

Referring to FIG. 1, the inventors of the present disclosure found that the main reason for the defects such as bright spots in the display panel is as follows. A reflective layer group 5 is arranged at a side of an insulating layer group 3 away from a first base substrate 1. A recessed structure is formed between two adjacent reflective portions 52. When forming the reflective layer group 5, a material for forming the reflective layer group 5 is coated on a side of the insulating layer group 3 away from the base substrate, and then masking, exposure, etching and other processes steps are carried out to form a plurality of reflective portions 52. Residues of the material of the reflective layer group 5 and photoresist may be formed in the recessed structure. The etching rate of layers of the reflective portions 52 is inconsistent, and this may result in that a part of film layers with a lower etching rate produce etching residues. These etching residues may also make reflective portions 52 of two adjacent pixels conductively connected, thereby causing defects of bright spots. In addition, when the gap between the reflective portions 52 of two adjacent pixels is too small, sidewalls of metal layers (silver, Ag) of the reflective portions 52 are exposed; when the display panel is operated at high temperature and high humidity or outdoors, it is easy for Ag ions to migrate, causing the reflective portions 52 of two adjacent pixels to be conductively connected, thereby leading to defects of bright spots. FIG. 2 is a schematic diagram showing a display effect of defects of bright spots. The white bright spots in the figure are defects.

An implementation of the present disclosure provides an array substrate 100. As shown in FIG. 3 to FIG. 15, the array substrate 100 may include a first base substrate 1, an insulating layer group 3 and a reflective layer group 5. The insulating layer group 3 is arranged at a side of the first base substrate. A first protruding portion 34 is provided at a side of the insulating layer group 3 away from the first base substrate 1. The reflective layer group 5 is arranged at a side of the insulating layer group 3 away from the first base substrate 1. The reflective layer group 5 includes a plurality of reflective portions 52. A first gap 51 is arranged between two adjacent reflective portions 52. The first protruding portion 34 is arranged in the first gap 51.

In the array substrate 100 of the present disclosure, on the one hand, the first protruding portion 34 is provided at a side of the insulating layer group 3 away from the first base substrate 1, and the first gap 51 is provided between two adjacent reflective portions 52. The first protruding portion 34 is filled in the first gap 51, and the first protruding portion 34 can isolate two adjacent reflective portions 52. Even if the display panel is operated at high temperature and high humidity or outdoors and Ag ions migrate, the Ag ions which migrate at both sides of the first protruding portion 34 need to climb up the sidewalls of the first protruding portion 34 and then migrate to the side of the first protruding portion 34 away from the first base substrate 1 to realize the conduction and connection between two adjacent reflective portions 52. Therefore, the first protruding portion 34 increases the migration path of Ag ions, so that even if the Ag ions of two adjacent reflective portions 52 migrate, it is difficult to realize conduction and connection. In this way, defects of bright spots are less likely to occur.

On the other hand, when forming the reflective portions 52, the material for forming the reflective layer group 5 is coated on the side of the insulating layer group 3 away from the base substrate, and then a plurality of reflective portions 52 are formed through masking, exposure, etching and other process steps. The first gap 51 is formed between two adjacent reflective portions 52. Therefore, the material of the reflective layer group 5 in the first gap 51 needs to be etched away. This part of material of the reflective layer group 5 that needs to be etched away is formed on the side of the first protruding portion 34 away from the first base substrate 1, which is easier to fully contact with the etching solution than being formed in the recessed structure. Thus, the replacement rate of the etching solution is fast (that is, the etching rate is high). This is beneficial to the etching of the reflective layer group 5, and it is not easy to produce metal residues, making it difficult to make a conductive connection between two adjacent reflective portions 52. Thus, defects of bright spots are not easy to occur.

Referring to the schematic diagram showing a display effect of the display panel according to an embodiment of the present disclosure shown in FIG. 3, there are almost no defects of bright spots in the figure.

It should be noted that, in this specification, a first direction X and a second direction Y are parallel to a surface of the first base substrate 1 close to a switch layer group 2, the first direction X intersects the second direction Y, for example, the first direction X may be perpendicular to the second direction Y. A third direction Z is perpendicular to the surface of the first base substrate 1 close to the switch layer group 2.

In an example implementation, the first base substrate 1 may be a glass substrate. Alternatively, in some other example implementations of the present disclosure, the first base substrate 1 may be quartz or the like. The first base substrate 1 may also include an insulating material layer, which may be arranged at a side of the glass substrate. The insulating material layer may be resinous material such as polyimide, polycarbonate, polyacrylate, polyetherimide, polyethersulfone, polyethylene glycol terephthalate, or polyethylene naphthalate.

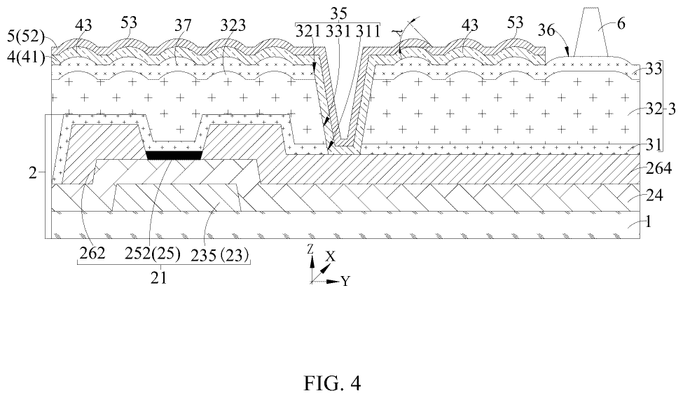

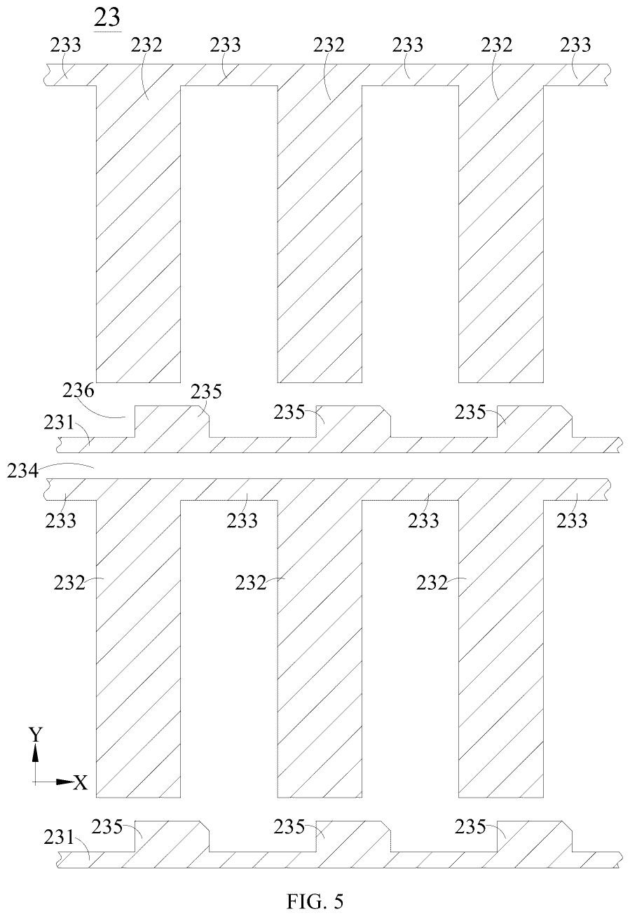

In an example implementation, as shown in FIG. 4 and FIG. 5, a gate layer 23 may be provided at a side of the first base substrate 1. The gate layer 23 may include a plurality of gate electrodes 235, a plurality of gate lines 231, a plurality of second sub-electrodes 232 and a plurality of connection portions 233. The second sub-electrodes 232 are arranged in strip shapes extending along the second direction Y.

The gate lines 231 extend along the first direction X. The first direction X is parallel to the surface of the first base substrate 1 close to the switch layer group 2. A plurality of gate electrodes 235 are connected to one gate line 231, and the gates 235 are located between the gate line 231 and second sub-electrode 232 which belong to the same pixel. Alternatively, a part of the gate line 231 may be used as the gate electrode(s) 235. The plurality of second sub-electrodes 232 are arranged in an array, and a plurality of second sub-electrodes 232 arranged along the first direction X form a row. A gate line 231 is arranged between two adjacent rows of second sub-electrodes 232, that is, the gate line 231 is arranged at a side of the second sub-electrodes 232 in the second direction Y. A connection portion 233 is connected between two adjacent second sub-electrodes 232 arranged along the first direction X, that is, multiple second sub-electrodes 232 in the same row are connected to each other through the connection portions 233. A second sub-electrode 232 may be a common sub-electrode. A common electrode is provided as an entire layer, and the second sub-electrodes 232 need to be connected as a whole.

A third gap 234 is provided between a second sub-electrode 232 and a gate line 231 which belong to different adjacent pixels. The third gap 234 extends along the first direction X. A sixth gap 236 is provided between a second sub-electrode 232 and a gate line 231 which belong to the same pixel. The sixth gap 236 extends along the first direction X. A width K6 of the sixth gap 236 in the second direction Y is larger than a width K3 of the third gap 234 in the second direction Y, so that there is enough space for accommodating a gate electrode 235 in the sixth gap 236.

In an example implementation, as shown in FIG. 4, a gate insulating layer 24 is arranged at a side of the gate layer 23 away from the first base substrate 1.

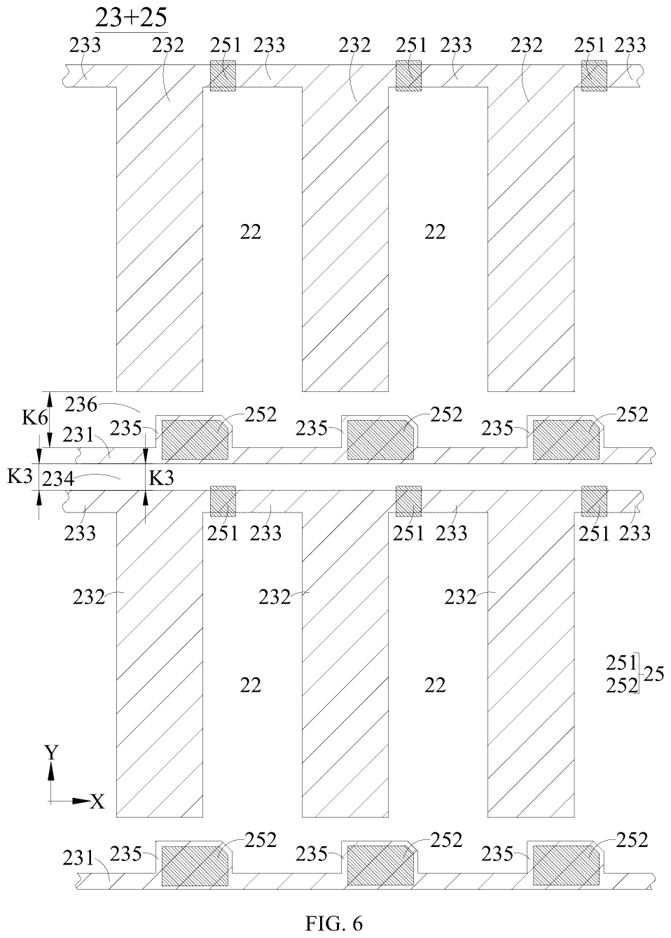

Referring to FIG. 4 and FIG. 6, an active layer 25 is arranged at a side of the gate insulating layer 24 away from the first base substrate 1. The active layer 25 may include a channel portion 252, a conductor portion and a filling portion 251. The channel portion 252 is arranged at a side of the gate electrode 235 away from the first base substrate 1. When a part of the gate line 231 is used as a gate electrode 235, a part of the gate line 231 facing the channel portion 252 is used as the gate electrode 235. Two conductor portions are connected to two ends of the channel portion 252 in one-to-one correspondence. The filling portion 251 is arranged at a side of the connection portion 233 away from the first base substrate 1, and covers at least part of the sidewall of the connection portion 233, so that the slope gradient of the sidewall of the connection portion 233 is reduced.

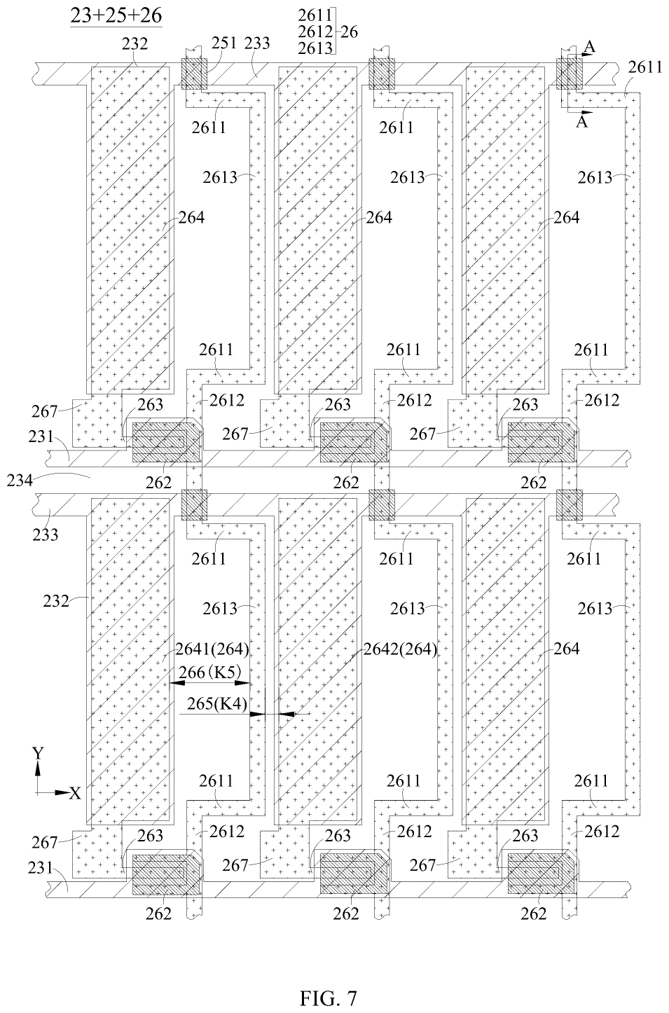

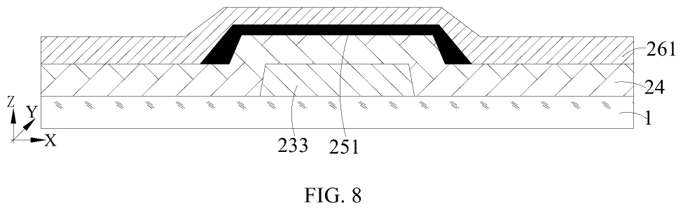

In an example implementation, as shown in FIG. 4, FIG. 7 and FIG. 8, a source-drain layer 26 is arranged at a side of the active layer 25 away from the first base substrate 1. The source-drain layer 26 may include a plurality of source electrodes 262, a plurality of drain electrodes 263, a plurality of data lines 261 and a plurality of light-shielding portions 264. The data line 261 extends along the second direction Y. The second direction Y is parallel to the surface of the first base substrate 1 close to the switch layer group 2. The second direction Y intersects the first direction X. For example, the second direction Y may be perpendicular to the first direction X. Therefore, the data lines 261 cross the connection portions 233. However, because the slope of the side surfaces of the connection portions 233 is relatively steep, and the thickness of the gate insulating layer 24 is relatively small, the planarization effect on the connection part 233 is relatively weak, and it is easy for the data lines 261 to be broken at the cross position with the connection portions 233, resulting in an open circuit. By arranging the filling portion 251 at the position where the connection portions 233 cross the data lines 261, that is, a part of a data line 261 is located at a side of the filling portion 251 away from a connection portion 233, the filling portion 251 can further flatten the slope of the side surface of the connection portion 233, and the data line 261 arranged on the filling portion 251 is not easy to be broken, and open circuit will not occur.

A data line 261 may include a plurality of first segments 2611, a plurality of second segments 2612 and a plurality of third segments 2613. The first segments 2611 extend along the first direction X, and the second segments 2612 and the third segments 2613 both extend along the second direction Y. The second segments 2612 are connected to a part of adjacent first segments 2611, and one of the second segments 2612 is connected to ends of two adjacent first segments 2611. The third segments 2613 are connected to other parts of adjacent first segments 2611, and one of the third segments 2613 is connected to other ends of two adjacent first segments 2611. The second segments 2612 and the third segments 2613 are arranged alternately. A plurality of first segments 2611, a plurality of second segments 2612 and a plurality of third segments 2613 are connected to form a “bow” shape (looks like an exaggerated curve of a bow). The length of a third segment 2613 in the second direction Y is greater than the length of a second segment 2612 in the second direction Y, so that a subsequently formed first electrode 41 overlaps with the third segment 2613 of a data line 261 of the pixel to form first parasitic capacitance, and overlaps with the second segment 2612 of a data line 261 in an adjacent pixel to form second parasitic capacitance. When the display panel adopts a column inversion mode to perform display, the polarities of voltages applied to two data lines 261 of adjacent pixels are opposite. In this way, when the capacitance value of the first parasitic capacitance and the capacitance value of the second parasitic capacitance in the pixel are non-zero capacitance values, under the action of the first parasitic capacitance and the second parasitic capacitance, the pulling effects of the two data lines 261 on the pixel voltage applied on the first electrode 41 can cancel each other (part or all of positive and negative effects cancel each other), and reduce or eliminate the influence of the data lines 261 on the display of the reflective display panel, and can increase the reflective area of the reflective layer group 5 to improve the display effect.

A second segment 2612, across a gate line 231, connects two pixels which are adjacent in the second direction Y. The second segment 2612 is connected to a source electrode 262. A third segment 2613 is located between two adjacent light-shielding portions 264. The distances between the third segment 2613 and the two adjacent light-shielding portions 264 are different; or, the distances between a light-shielding portion 264 and two data lines 261 at both sides of the light-shielding portion 264 are different. Specifically, the width K5 of the fifth gap 266 between the third segment 2613 and a first light-shielding portion 2641 is greater than the width K4 of the fourth gap 265 between the third segment 2613 and a second light-shielding portion 2642. The first light-shielding portion 2641 and the third segment 2613 belong to the same pixel, and the second light-shielding portion 2642 and the third segment 2613 belong to different adjacent pixels.

The light-shielding portions 264 are set as strips extending along the second direction Y. A plurality of light-shielding portions 264 are arranged in an array. A light-shielding portion 264 is arranged at a side of a data line 261 in the first direction X. The orthographic projection of a light-shielding portion 264 on the first base substrate 1 is located within the orthographic projection of a second sub-electrode 232 on the first base substrate. For example, the orthographic projection of the light-shielding portion 264 on the first base substrate 1 may coincide with the orthographic projection of the second sub-electrode 232 on the first base substrate 1; or, an edge line of the orthographic projection of the light-shielding portion 264 on the first base substrate 1 is located at an inner side of the outermost edge line of the orthographic projection of the second sub-electrode 232 on the first base substrate 1, and a difference between the edge line of the orthographic projection of the light-shielding portion 264 on the first base substrate 1 and the outermost edge line of the orthographic projection of the second sub-electrode 232 on the first base substrate 1 is greater than or equal to 0 μm and less than or equal to 10 μm. An overlapping portion of the light-shielding portion 264 and the second sub-electrode 232 forms a storage capacitor. The overlapping portion of the light-shielding portion 264 and the second sub-electrode 232 is designed to be as large as the storage capacitor needs.

An end of a source electrode 262 is connected to a data line 261, and the other end of the source electrode 262 is connected to a conductor portion. An end of a drain electrode 263 is connected to a light-shielding portion 264, and the other end of the drain electrode 263 is connected to another conductor portion. Specifically, the source-drain layer 26 may further include a connection block 267, which is connected between a light-shielding portion 264 and a drain electrode 263. There is no overlap between the orthographic projection of the connection block 267 on the first base substrate 1 and the orthographic projection of a gate electrode 235 on the first base substrate 1, and the orthographic projection of the connection block 267 on the first base substrate 1 is located at a side of the source electrode 262 away from a data line 261. The connection block(s) 267 is (are) provided to facilitate subsequent connection with the first electrode 41.

A light-shielding portion 264, a second sub-electrode 232, a gate electrode 235, a channel portion 252, a source electrode 262, a drain electrode 263, and two conductor portions form a switch unit 21, which is a thin film transistor.

It should be noted that the thin-film transistors described in some implementations of the present disclosure are bottom-gate thin-film transistors. In other example implementations of the present disclosure, the thin-film transistors may be top-gate or double-gate type, and the specific structure thereof will not be described here. Furthermore, when using thin-film transistors with opposite polarities or when the direction of current changes during circuit operation, the functions of the “source electrode 262” and “drain electrode 263” may be interchanged. Therefore, in the present disclosure, “source electrode 262” and “drain electrode 263” can be interchanged.

A second gap 22 is provided between two adjacent switch units 21, and the second gap 22 may be a gap between two adjacent second sub-electrodes 232. Second gaps 22 are arranged in a grid shape. The orthographic projection of a first protruding portion 322 on the first base substrate 1 is located within the orthographic projection of a second gap 22 on the first base substrate 1. The range of the second gap 22 is relatively large, and the specific position of the first protruding portion 322 will be described below with an example.

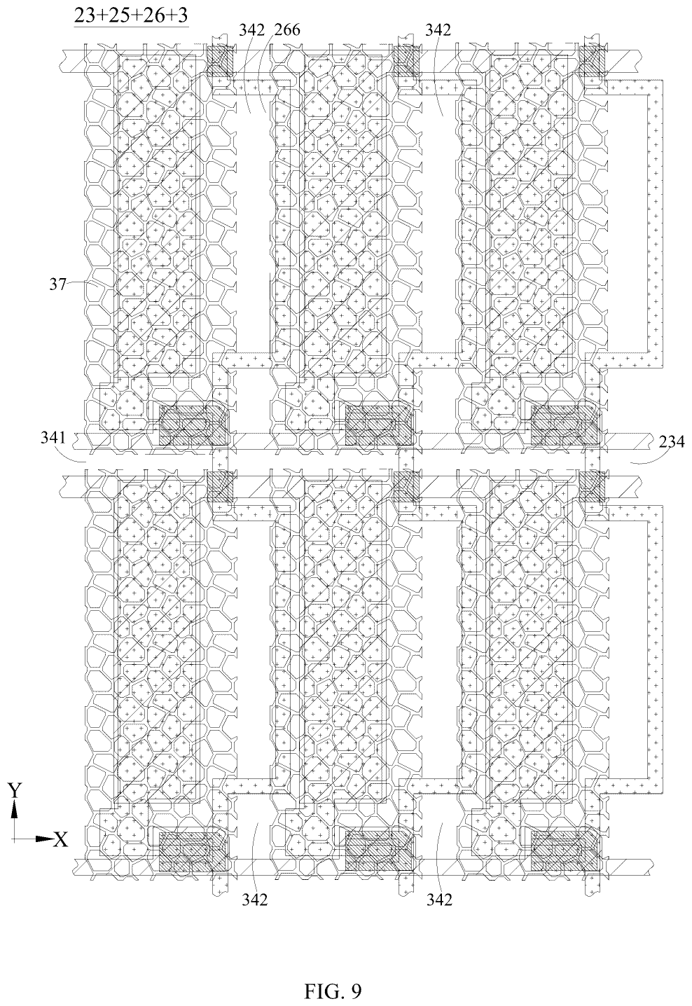

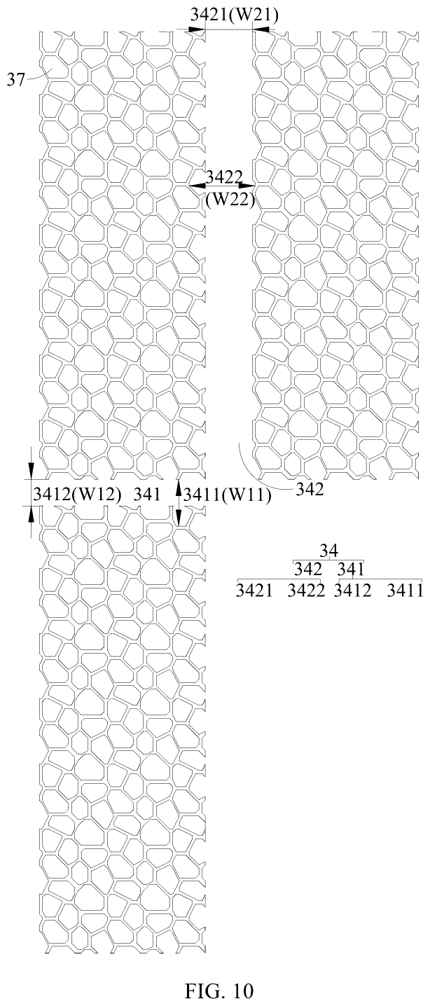

In an example implementation, referring to FIG. 4 and FIG. 9 and FIG. 10, a part of the insulating layer group 3 in FIG. 9 and FIG. 10 in which no dot fill is added is a protruded part, and a part of the insulating layer group 3 in which dot fill is added is a recessed part. The insulating layer group 3 is arranged at a side of the source-drain layer 26 away from the first base substrate 1. The insulating layer group 3 may include a first protective layer 31, an insulating layer 32 and a second protective layer 33. The first protective layer 31 is arranged at a side of the source-drain layer 26 away from the first base substrate 1. The first protective layer 31 is provided with a first sub-via hole 311, and the first sub-via hole 311 is connected to a light-shielding portion 264. The material of the first protective layer 31 may be an inorganic material, for example, silicon nitride, silicon oxide, and the like. The thickness of the first protective layer 31 is greater than or equal to 100 nm and less than or equal to 500 nm.

The insulating layer 32 is arranged at a side of the first protective layer 31 away from the first base substrate 1. The insulating layer 32 is provided with a second sub-via hole 321, which communicates with the first sub-via hole 311, so that the second sub-via hole 321 is connected to the light-shielding portion 264. The material of the insulating layer 32 may be an organic material, such as polyimide, polycarbonate, polyacrylate and the like. The thickness of the insulating layer 32 is greater than or equal to 0.5 μm and less than or equal to 5 μm. Because the thickness of the insulating layer 32 is relatively large, the insulating layer 32 is etched to form a protruding portion, and when the second protective layer 33 is formed at a side of the insulating layer 32 away from the base substrate, the first protruding portion 34 will naturally be formed at the second protective layer 33. Moreover, the material of the insulating layer 32 may be photoresist. When forming the protruding portion and the second sub-via hole 321 at the insulating layer 32, only exposure and development are needed, which can save process steps. When forming a protruding portion at other film layers, after exposure and development, other film layers need to be etched using photoresist as a mask.

The second protective layer 33 is arranged at a side of the insulating layer 32 away from the first base substrate 1, and a part of the second protective layer 33 also covers the hole wall of the second sub-via hole 321. The second protective layer 33 is provided with a third sub-via hole 331. The third sub-via hole 331 communicates with the second sub-via hole 321 and the first sub-via hole 311, so that the third sub-via hole 331 is connected to the light-shielding portion 264. The first sub-via hole 311, the second sub-via hole 321 and the third sub-via hole 331 form a first via hole 35. The first via hole 35 is connected to the light-shielding portion 264. The material of the second protective layer 33 may be an inorganic material, and the material of the second protective layer 33 may be the same as that of the first protective layer 31, for example, it may be silicon nitride, silicon oxide and the like.

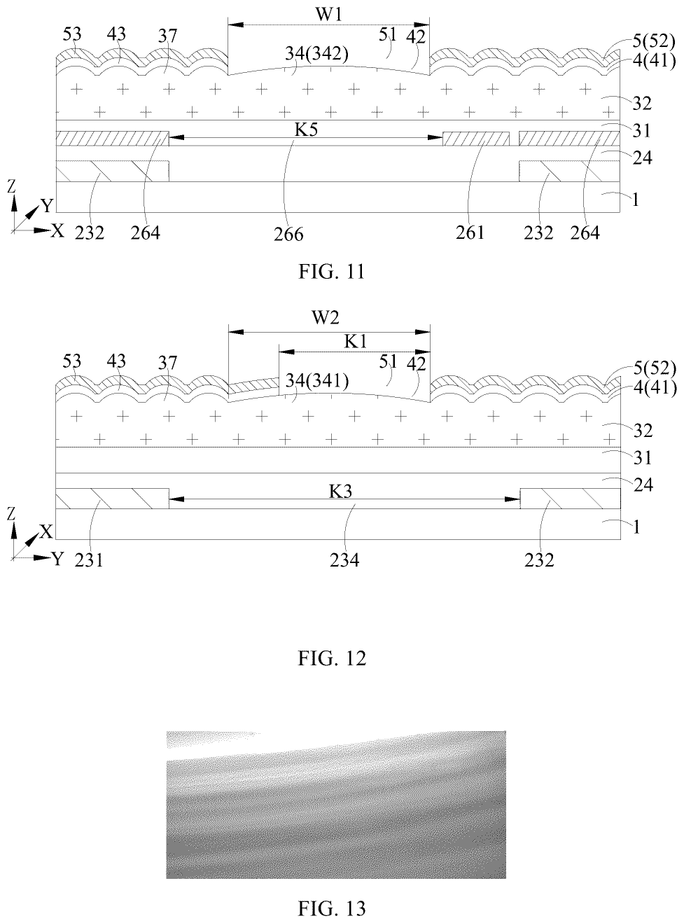

The first protective layer 31 and the second protective layer 33 can protect the insulating layer 32. Moreover, the second protective layer 33 can block the gas that escapes from the insulating layer 32, so as to prevent air bubbles from being generated after the array substrate 100 and the color filter substrate 200 form a cell. After the insulating layer 32 is formed, a high-temperature baking process is required to cause most of the gas in the insulating layer 32 to escape. However, for a display panel with a larger size (for example, greater than 13 inches), a high-temperature process is required. During the high-temperature process, the gas escapes from the insulating layer 32, and due to the large area, the gap that escapes from the insulating layer 32 will generally form bubbles and affect the display effect. The second protective layer 33 can block the gas that escapes from the insulating layer 32, thus avoiding generation of bubbles after the cell process. For a display panel with a small size (for example, less than or equal to 13 inches), although the high-temperature process is required, due to the small area, the gas that escapes rarely forms bubbles, and the second protective layer 33 may not be provided. Therefore, in other example implementations of the present disclosure, referring to FIG. 11, the insulating layer group 3 may only include the first protective layer 31 and the insulating layer 32. Of course, in some other example implementations of the present disclosure, the insulating layer group 3 may also include more insulating material layers, for example, may also include a passivation layer, a buffer layer, and the like. Moreover, the protruding portion can be provided in any layer having a relatively large thickness.

Referring to FIG. 9, FIG. 10 and FIG. 11, when the insulating layer group 3 includes a first protective layer 31 and an insulating layer 32, a first protruding portion 34 and a second protruding portion 37 are provided at the insulating layer 32.

Specifically, the first protruding portion 34 is arranged at a surface of the insulating layer 32 away from the first base substrate 1. The first protruding portion 34 may include a plurality of first protruding strips 341 extending along the first direction X and a plurality of second protruding strips 342 extending in the direction Y. The width W2 of a first protruding strip 341 in the second direction Y is greater than or equal to 1 micron and less than or equal to 12 microns, for example, the width may be 5 microns, 6 microns, 8 microns, etc. The width W1 of a second protruding strip 342 in the first direction X is greater than or equal to 4 microns and less than or equal to 10 microns, for example, the width may be 5 microns, 6 microns, 7 microns, 7.8 microns, 8 microns, etc. A plurality of first protruding strips 341 and a plurality of second protruding strips 342 are cross-connected to form a plurality of grids, and a plurality of second protruding portions 37 are arranged in the grids.

A first protruding strip 341 at least includes a first part 3411 and a second part 3412. The width W11 of the first part 3411 in the second direction Y is different from the width W12 of the second part 3412 in the second direction Y. The width of the first part 3411 in the second direction Y may be greater than the width of the second part 3412 in the second direction Y; or the width of the first part 3411 in the second direction Y may be smaller than the width of the second part 3412 in the second direction Y. And, the first protruding strip 341 may further include more parts having widths in the second direction Y which are different from the widths of the first part 3411 and the second part 3412. To be more specific, the width setting of the first protruding strip 341 is irregular.

A second protruding strip 342 includes at least a third part 3421 and a fourth part 3422. The width W21 of the third part 3421 in the first direction X is different from the width W22 of the fourth part 3422 in the first direction X. The width of the third part 3421 in the first direction X may be greater than the width of the fourth part 3422 in the first direction X; or, the width of the third part 3421 in the first direction X may be smaller than the width of the fourth part 3422 in the first direction X. And, the second protruding strip 342 may further include more parts having widths in the first direction X which are different from the widths of the third part 3421 and the fourth part 3422. To be more specific, the width of the second protruding strip 342 is irregular.

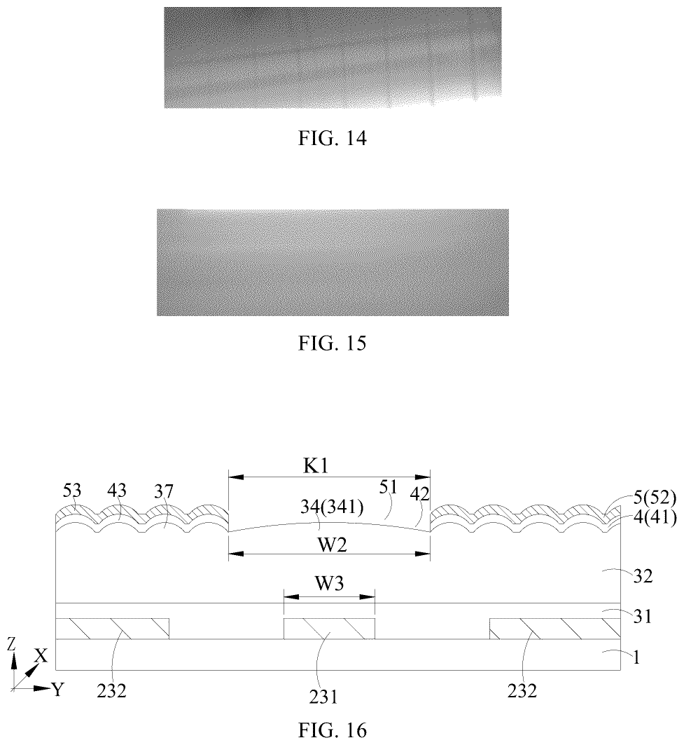

Referring to FIG. 13 to FIG. 15, FIG. 13 is a display effect diagram when the second protruding portions 37 are set as regular, FIG. 14 is a display effect of a case where a part of first protruding portions 34 are set as regular and another part of first protruding portions 34 are set as irregular, and FIG. 15 is a schematic diagram of a display effect when first protruding portions 34 are set as irregular. The more regular the setting of the second protruding portions 37, the more serious the rainbow pattern will be, which affects the display effect.

It should be noted that the second protruding portions 37 being set as irregular refers to that not only the shapes of the second protruding portions 37 are irregular, but also the arrangement of the plurality of second protruding portions 37 is irregular.

Since the second protruding portions 37 are set as irregular, a part of the second protruding portions 37 are connected with the first protruding portion 34, so that the width of the first protruding portion 34 is irregular.

In some example implementations of the present disclosure, please continue to refer to FIG. 9, FIG. 10, and FIG. 12, the orthographic projection of a first protruding portion 34 on the base substrate overlaps with the orthographic projection of a third gap 234 on the base substrate. Specifically, the orthographic projection of a first protruding strip 341 on the base substrate overlaps with the orthographic projection of the third gap 234 on the base substrate. For example, it may be that the orthographic projection of the first protruding strip 341 on the base substrate is within the orthographic projection of the third gap 234 on the base substrate; or a part of the orthographic projection of the first protruding strip 341 on the base substrate overlaps with a part of the orthographic projection of the third gap 234 on the base substrate. And, the width W2 of the first protruding strip 341 in the second direction Y is smaller than the width K3 of the third gap 234 in the second direction Y. It should be noted that the width W2 of the first protruding strip 341 in the second direction Y refers to the minimum width of the first protruding strip 341. The maximum width of the first protruding strip 341 may be greater than or equal to the width of the third gap 234 in the second direction Y.

Referring to FIG. 11, the orthographic projection of the first protruding portion 34 on the base substrate overlaps the orthographic projection of the fifth gap 266 on the base substrate. Specifically, the orthographic projection of the second protruding strip 342 on the base substrate overlaps with the orthographic projection of the fifth gap 266 on the base substrate. For example, it may be that: the orthographic projection of the second protruding strip 342 on the base substrate is within the orthographic projection of the fifth gap 266 on the base substrate; or, a part of the orthographic projection of the second protruding strip 342 on the base substrate overlaps with a part of the orthographic projection of the fifth gap 266 on the base substrate. And, the width W1 of the second protruding strip 342 in the first direction X is smaller than the width K5 of the fifth gap 266 in the first direction X. It should be noted that, here, the width W1 of the second protruding strip 342 in the first direction X refers to the minimum width of the second protruding strip 342. The maximum width of the second protruding strip 342 may be greater than or equal to the width K5 of the fifth gap 266 in the first direction X.

FIG. 16 is a schematic cross-sectional view of an array substrate cut along the second direction according to another example implementation of the present disclosure, and it does not belong to the same example implementation as the array substrate in FIG. 9. The orthographic projection of the first protruding portion 34 on the base substrate overlaps with the orthographic projection of a gate line 231 on the base substrate. Specifically, the orthographic projection of the first protruding strip 341 on the base substrate overlaps with the orthographic projection of the gate line 231 on the base substrate. For example, it may be that: the orthographic projection of the first protruding strip 341 on the base substrate coincides with the orthographic projection of the gate line 231 on the base substrate; or, a part of the orthographic projection of the first protruding strip 341 on the base substrate may coincide with a part of the orthographic projection of the gate line 231 on the base substrate; or, an edge line of the orthographic projection of the first protruding strip 341 on the base substrate may be located at an inner side of an edge line of the orthographic projection of the gate line 231 on the base substrate.

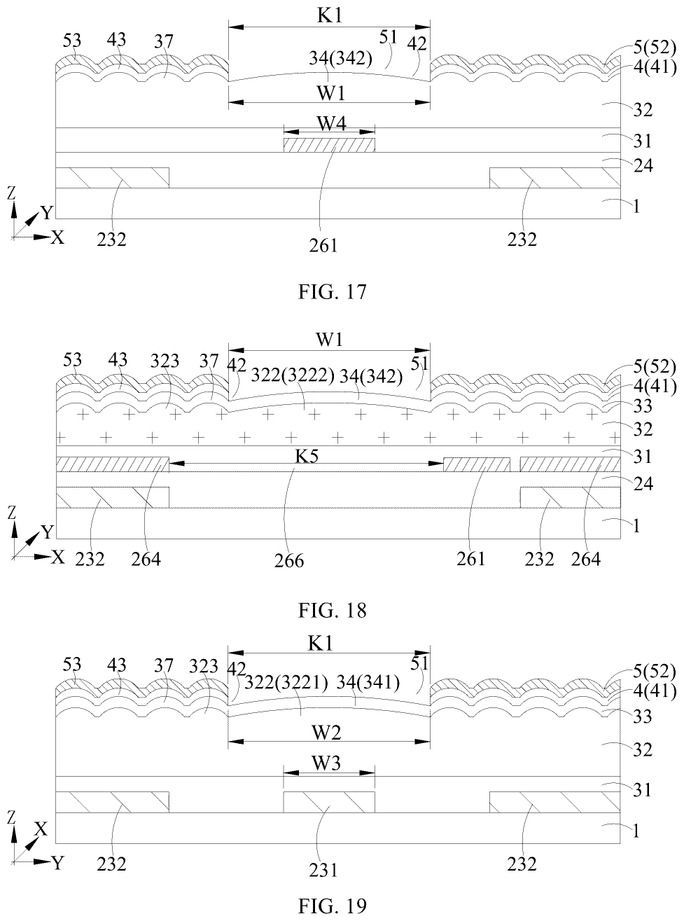

FIG. 17 is a schematic cross-sectional view of an array substrate cut along the first direction according to another example implementation of the present disclosure, and it does not belong to the same example implementation as the array substrate in FIG. 9. The orthographic projection of the first protruding portion 34 on the base substrate overlaps with the orthographic projection of a data line 261 on the base substrate. Specifically, the orthographic projection of the second protruding strip 342 on the base substrate overlaps with the orthographic projection of the data line 261 on the base substrate. For example, it may be that: the orthographic projection of the second protruding strip 342 on the base substrate coincides with the orthographic projection of the data line 261 on the base substrate; or, a part of the orthographic projection of the second protruding strip 342 on the base substrate may coincide with a part of the orthographic projection of the data line 261 on the base substrate; or, an edge line of the orthographic projection of the second protruding strip 342 on the base substrate may be located at an inner side of an edge line of the orthographic projection of the data line 261 on the base substrate.

In addition, referring to FIG. 16 and FIG. 17, the width W2 of the first protruding strip 341 in the second direction Y may be greater than or equal to the width W3 of the gate line 231 in the second direction Y, and the width W1 of the second protruding strip 342 in the first direction X may be greater than or equal to the width W4 of the data line 261 in the first direction X. The first protruding portion 34 is made wide enough, so that the first protruding portion can fill the first gap, thus avoiding the formation of a recessed structure between the reflective portions and the first protruding portion 34 and the material of the reflective layer group being deposited in the recessed structure which results in a conductive connection between two adjacent reflective portions.

It should be noted that the width W2 of the first protruding strip 341 in the second direction Y refers to the minimum width of the first protruding strip 341, and the width W1 of the second protruding strip 342 in the first direction X refers to the minimum width of the second protruding strip 342.

Referring to FIG. 9, FIG. 10, FIG. 16 and FIG. 17, a plurality of second protruding portions 37 are also provided at a surface of the insulating layer 32 away from the first base substrate 1. The second protruding portions 37 and the first protruding portion 34 are formed by the same patterning process and therefore, the height of the second protruding portions 37 in the third direction Z is the same as the height of the first protruding portion 34 in the third direction Z. The height of the sidewall of a second protruding portion 37 in the second direction YZ decreases as the distances from the center of the second protruding portion 37 on the first plane increases. The first plane is parallel with a plane of the first base substrate 1 close to the switch layer group 2, that is, the first plane is a plane formed by the first direction X and the second direction Y, and the third direction Z is perpendicular to the first plane. For example, the sidewall of a second protruding portion 37 may be set as a curved surface, the curved surface may be a circular arc surface, an elliptical arc surface, etc. Specifically, the second protruding portion 37 may be set as a spherical cap structure, an ellipsoid cap structure, etc. The sidewall of the second protruding portion 37 may also be set as a slope. Specifically, in order to ensure that the subsequently formed second protruding portion 37 has a sufficient reflective surface, the second protruding portion 37 may not be provided with an upper top surface, that is, the second protruding portion 37 may be provided as various pyramid structures. In addition, the second protruding portions 37 may be set as various irregular shapes, and the arrangement of the second protruding portions 37 may also be irregular.

It should be noted that the first protruding portion 34 and the second protruding portions 37 at the insulating layer 32 are formed by the same patterning process, and therefore, the height of the first protruding portion 34 in the third direction Z is the same as the height of the second protruding portions 37 in the third direction Z.

In some other example implementations of the present disclosure, the first protruding portion 34 and the second protruding portions 37 may be formed by different patterning processes. Therefore, the height of the first protruding portion 34 in the third direction Z may be different from the height of the second protruding portions 34 in the third direction Z. Generally, it can be set that the height of the first protruding portion 34 in the third direction Z is greater than the height of the second protruding portions 37 in the third direction Z. Further, it can be that the height of a surface of the first protruding portion 34 away from the first base substrate 1 in the third direction Z is higher than the height of a surface of the reflective layer group 5 (reflective portions 52) away from the first base substrate 1 in the third direction Z, so as to ensure that a subsequently formed first electrode 41 and a reflective portions 52 are completely disconnected at the first protruding portion 34.

It is also possible to set the light transmittance of the mask at the first protruding portion 34 and the second protruding portions 37 differently. Generally, it can be set such that the light transmittance at the first protruding portion 34 is relatively low, and the light transmittance at the second protruding portions 37 is relatively high. In this way, the height of the first protruding portion 34 in the third direction Z can be greater than the height of the second protruding portions 37 in the third direction Z. Further, it can be that the height of a surface of the first protruding portion 34 away from the first base substrate 1 in the third direction Z is higher than the height of a surface of the reflective layer group 5 (reflective portions 52) away from the first base substrate 1 in the third direction Z, so as to ensure that a subsequently formed first electrode 41 and a reflective portion 52 are completely disconnected at the first protruding portion 34. Of course, it can be understood that, in a case that the photoresist used is a negative photoresist, the above light transmittance can be set to be an opposite state.

Referring to FIG. 9, FIG. 10 and FIG. 18 to FIG. 20, in a case where the insulating layer group 3 includes a first protective layer 31, an insulating layer 32 and a second protective layer 33, a fourth protruding portion and a plurality of fifth protruding portions are provided at the insulating layer 32, and the first protruding portion 34 corresponding to the fourth protruding portion 322 and the second protruding portions 37 corresponding to the fifth protruding portions 323 are provided at the second protective layer 33. Specifically, the thickness of the second protective layer 33 is greater than or equal to 50 nm and less than or equal to 600 nm. The first protruding portion 34 and the plurality of second protruding portions 37 are formed at a surface of the second protective layer 33 away from the first base substrate 1. The first protruding portion 34 is arranged opposite to the fourth protruding portion 322, that is, the first protruding portion part 34 is located at a side of the fourth protruding portion 322 away from the first base substrate 1. The second protruding portions 37 are arranged opposite to the fifth protruding portions 323, that is, the second protruding portions 37 are located at a side of the fifth protruding portions 323 away from the first base substrate 1.

Specifically, the fourth protruding portion 322 is provided at a side of the insulating layer 32 away from the first base substrate 1. The fourth protruding portion 322 may include a plurality of third protruding strips 3221 extending along the first direction X and a plurality of fourth protruding strips 3222 extending along the second direction Y. The plurality of third protruding strips 3221 and the plurality of fourth protruding strips 3222 are cross-connected to form a plurality of grids, and a plurality of fifth protruding portions 323 are arranged in the grids.

The second protective layer 33 is arranged at a side of the insulating layer 32 away from the first base substrate 1 and the thickness of the second protective layer 33 is relatively small, and therefore the first protruding portion 34 is formed at a surface of the second protective layer 33 away from the first base substrate 1. The first protruding portion 34 may include a plurality of first protruding strips 341 extending along the first direction X and a plurality of second protruding strips 342 extending along the second direction Y. The second protective layer 33 covers the surface of the third protruding strips 3221 away from the base substrate to form the first protruding strips 341. The first protruding strips 341 are arranged opposite to the third protruding strips 3221, and the orthographic projection of one of the third protruding strips 3221 on the first base substrate 1 is located within the orthographic projection of one of the first protruding strips 341 on the first base substrate 1. The second protective layer 33 covers the surface of the fourth protruding strips 3222 away from the base substrate to form the second protruding strips 342. The second protruding strips 342 are arranged opposite to the fourth protruding strips 3222, and the orthographic projection of one of the fourth protruding strips 3222 on the first base substrate 1 is located within the orthographic projection of one of the second protruding strips 342 on the first base substrate 1.

A third protruding strip 3221 includes at least a fifth part and a sixth part. The width of the fifth part in the second direction Y is different from the width of the sixth part in the second direction Y. The width of the fifth part in the second direction Y may be greater than the width of the sixth part in the second direction Y, or the width of the fifth part in the second direction Y may be smaller than the width of the sixth part in the second direction Y. And, the third protruding strip 3221 may also include more parts with widths in the second direction Y which are different from the widths of the sixth part and the fifth part. To be more specific, the width setting of the third protruding strip 3221 is irregular.

Then, a first protruding strip 341 arranged opposite to the third protruding strip 3221 may at least include a first part 3411 and a second part 3412. The first part 3411 is arranged opposite to the fifth portion, and the second part 3412 is arranged opposite to the sixth portion. The width of the first part 3411 in the second direction Y is different from the width of the second part 3412 in the second direction Y. The width of the first part 3411 in the second direction Y may be greater than the width of the second part 3412 in the second direction Y, or the width of the first part 3411 in the second direction Y may be smaller than the width of the second part 3412 in the second direction Y. And, the first protruding strip 341 may also include more parts with widths in the second direction Y which are different from the widths of the first part 3411 and the second part 3412. To be more specific, the width setting of the first protruding strip 341 is irregular.

A fourth protruding strip 3222 includes at least a seventh part and an eighth part. The width of the seventh part in the first direction X is different from the width of the eighth part in the first direction X. The width of the seventh part in the first direction X may be greater than the width of the eighth part in the first direction X, or the width of the seventh part in the first direction X may be smaller than the width of the eighth part in the first direction X. And, the fourth protruding strip 3222 may also include more parts with widths in the first direction X which are different from the widths of the seventh part and the eighth part. To be more specific, the width setting of the fourth protruding strip 3222 is irregular.

Then, a second protruding strip 342 arranged opposite to the fourth protruding strip 3222 may at least include a third part 3421 and a fourth part 3422. The third part 3421 is arranged opposite to the seventh portion, and the fourth part 3422 is arranged opposite to the eighth portion. The width of the third part 3421 in the first direction X is different from the width of the fourth part 3422 in the first direction X. The width of the third part 3421 in the first direction X may be greater than the width of the fourth part 3422 in the first direction X, or the width of the third part 3421 in the first direction X may be smaller than the width of the fourth part 3422 in the first direction X. And, the second protruding strip 342 may also include more parts with widths in the first direction X which are different from the widths of the third part 3421 and the fourth part 3422. To be more specific, the width setting of the second protruding strip 342 is irregular.

In some other example implementations of the present disclosure, referring to FIGS. 9 to 18, the orthographic projection of the fourth protruding portion 322 on the base substrate overlaps with the orthographic projection of the third gap 234 on the base substrate, and the width of the fourth protruding portion 322 in the second direction Y is smaller than the width of the third gap 234 in the second direction Y. Specifically, the orthographic projection of the third protruding strip 3221 on the base substrate overlaps with the orthographic projection of the third gap 234 on the base substrate. For example, the orthographic projection of the third protruding strip 3221 on the base substrate may be located within the orthographic projection of the third gap 234 on the base substrate; or, a part of the orthographic projection of the third protruding strip 3221 on the base substrate may overlap with a part of the orthographic projection of the third gap 234 on the base substrate. The width of the third protruding strip 3221 in the second direction Y is smaller than the width of the third gap 234 in the second direction Y.

Then, the orthographic projection of the first protruding strip 341 on the base substrate overlaps with the orthographic projection of the third gap 234 on the base substrate. For example, the orthographic projection of the first protruding strip 341 on the base substrate may be located within the orthographic projection of the third gap 234 on the base substrate; or, a part of the orthographic projection of the first protruding strip 341 on the base substrate may overlap with a part of the orthographic projection of the third gap 234 on the base substrate. The width of the first protruding strip 341 in the second direction Y is smaller than the width of the third gap 234 in the second direction Y.

The orthographic projection of the fourth protruding portion 322 on the base substrate overlaps with the orthographic projection of the fifth gap 266 on the base substrate, and the width of the fourth protruding portion 322 in the first direction X is smaller than the width of the fifth gap 266 in the first direction X. Specifically, the orthographic projection of the fourth protruding strip 3222 on the base substrate overlaps with the orthographic projection of the fifth gap 266 on the base substrate. For example, the orthographic projection of the fourth protruding strip 3222 on the base substrate may be located within the orthographic projection of the fifth gap 266 on the base substrate; or, a part of the orthographic projection of the fourth protruding strip 3222 on the base substrate may overlap with a part of the orthographic projection of the fifth gap 266 on the base substrate. The width of the fourth protruding strip 3222 in the first direction X is smaller than the width of the fifth gap 266 in the first direction X.

Then, the orthographic projection of the second protruding strip 342 on the base substrate overlaps with the orthographic projection of the fifth gap 266 on the base substrate. For example, the orthographic projection of the second protruding strip 342 on the base substrate may be located within the orthographic projection of the fifth gap 266 on the base substrate; or, a part of the orthographic projection of the second protruding strip 342 on the base substrate may overlap with a part of the orthographic projection of the fifth gap 266 on the base substrate. The width of the second protruding strip 342 in the first direction X is smaller than the width of the fifth gap 266 in the first direction X.

Referring to FIG. 19, the orthographic projection of the fourth protruding portion 322 on the base substrate overlaps with the orthographic projection of a gate line 231 on the base substrate. Specifically, the orthographic projection of the third protruding strip 3221 on the base substrate overlaps with the orthographic projection of the gate line 231 on the base substrate. For example, the orthographic projection of the third protruding strip 3221 on the base substrate may coincide with the orthographic projection of the gate line 231 on the base substrate; or, a part of the orthographic projection of the third protruding strip 3221 on the base substrate may coincide with a part of the orthographic projection of the gate line 231 on the base substrate; or, an edge line of the orthographic projection of the third protruding strip 3221 on the base substrate may be located at an inner side of an edge line of the orthographic projection of the gate line 231 on the base substrate.

Then, the orthographic projection of the first protruding strip 341, which is arranged opposite to the third protruding strip 3221, on the base substrate overlaps with the orthographic projection of the gate line 231 on the base substrate. For example, the orthographic projection of the first protruding strip 341 on the base substrate may coincide with the orthographic projection of the gate line 231 on the base substrate; or, a part of the orthographic projection of the first protruding strip 341 on the base substrate may coincide with a part of the orthographic projection of the gate line 231 on the base substrate; or, an edge line of the orthographic projection of the first protruding strip 341 on the base substrate may be located at an inner side of an edge of the orthographic projection of the gate line 231 on the base substrate.

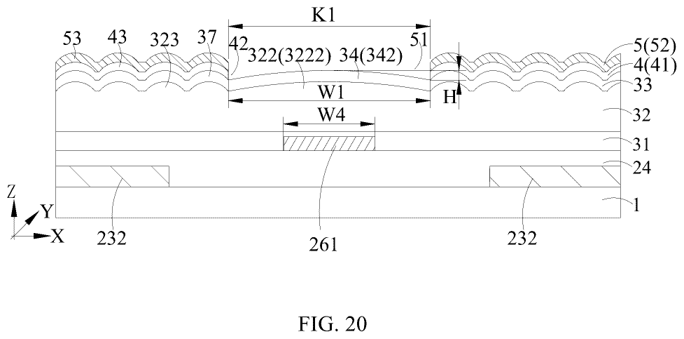

Referring to FIG. 20, the orthographic projection of the fourth protruding portion 322 on the base substrate overlaps with the orthographic projection of a data line 261 on the base substrate. Specifically, the orthographic projection of the fourth protruding strip 3222 on the base substrate overlaps with the orthographic projection of the data line 261 on the base substrate. For example, the orthographic projection of the fourth protruding strip 3222 on the base substrate may coincide with the orthographic projection of the data line 261 on the base substrate; or, a part of the orthographic projection of the fourth protruding strip 3222 on the base substrate may coincide with a part of the orthographic projection of the data line 261 on the base substrate; or, an edge line of the orthographic projection of the fourth protruding strip 3222 on the base substrate may be located at an inner side of an edge of the orthographic projection of the data line 261 on the base substrate.

Then, the orthographic projection of the second protruding strip 342, which is arranged opposite to the fourth protruding strip 3222, on the base substrate overlaps with the orthographic projection of the data line 261 on the base substrate. For example, the orthographic projection of the second protruding strip 342 on the base substrate may coincide with the orthographic projection of the data line 261 on the base substrate; or, a part of the orthographic projection of the second protruding strip 342 on the base substrate may coincide with a part of the orthographic projection of the data line 261 on the base substrate; or, an edge line of the orthographic projection of the second protruding strip 342 on the base substrate may be located at an inner side an edge of the orthographic projection of the data line 261 on the base substrate.

In some example implementations of the present disclosure, the width of the fourth protruding portion 322 in the second direction Y is greater than or equal to the width of the gate line 231 in the second direction Y, and the width of the fourth protruding portion 322 in the first direction X is greater than the width of the data line 261 in the first direction X. Specifically, the width of the third protruding strip 3221 in the second direction Y is greater than or equal to the width of the gate line 231 in the second direction Y, and the width of the fourth protruding strip 3222 in the first direction X is greater than the width of the data line 261 in the first direction X.

Then, referring to FIG. 19 and FIG. 20, the width W2 of the first protruding strip 341 in the second direction Y is greater than or equal to the width W3 of the gate line 231 in the second direction Y, and the width W1 of the second protruding strip 342 in the first direction X is larger than the width W4 of the data line 261 in the first direction X.

Optionally, the width W of the first protruding strip 341 in the second direction Y is approximately 6 microns, the width W of the second protruding strip 342 in the first direction X is approximately 6 microns, and the height H of the first protruding portion in the third direction is greater than or equal to 0.1 micron and less than or equal to 1 micron, for example, it can be 0.2 μm, 0.25 μm, 0.3 μm, 0.4 μm, 0.45 μm, 0.5 μm, 0.53 μm, 0.64 μm, 0.7 μm, 0.85 μm, 0.9 μm, 0.94 μm etc.

A plurality of fifth protruding portions 323 are also provided at a side of the insulating layer 32 away from the first base substrate 1. The height of the sidewall of a fifth protruding portion 323 in the fifth direction Z decreases as the distance from the center of the fifth protruding portion 323 on the first plane increases. The first plane is parallel to a surface of the first base substrate 1 close to the switch layer group 2. That is, the first plane is a plane formed by the first direction X and the second direction Y. The fifth direction Z is perpendicular to the first plane. For example, the sidewall of a fifth protruding portion 323 may be set as a curved surface, and the curved surface may be a circular arc surface, an elliptical arc surface, etc. Specifically, the fifth protruding portion 323 may be set as a spherical cap structure, an ellipsoid cap structure, etc. The sidewall of the fifth protruding portion 323 may also be set as a slope. Specifically, in order to ensure that the second protruding portion 37 formed subsequently has a sufficient reflective surface, the fifth protruding portion 323 may be not be provided with an upper top surface, that is, the fifth protruding portion 323 may be provided as various pyramid structures. In addition, the fifth protruding portions 323 may be set as various irregular shapes, and the arrangement of the fifth protruding portions 323 may also be irregular.

The height of the sidewall of a second protruding portion 37 in the fifth direction Z also decreases as the distance from the center of the second protruding portion 37 on the first plane increases. For example, a surface of the second protruding portion 37 away from the first base substrate 1 may be set as a curved surface. In a case where the sidewall of the fifth protruding portion 323 is a circular arc surface or an elliptical arc surface, etc., correspondingly, the sidewall of the second protruding portion 37 is a circular arc surface, an ellipse arc surface, etc.; in a case where the fifth protruding portion 323 is set as a spherical cap structure, an ellipsoid cap structure, etc., correspondingly, the second protruding portion 37 is set as a spherical cap structure, an ellipsoid cap structure, etc.. The surface of the second protruding portion 37 away from the first base substrate 1 may also be set as a slope. In a case where the fifth protruding portion 323 is set as various pyramid structures, correspondingly, the second protruding portion 37 is also set as various pyramid structures. When the fifth protruding portions 323 are set as various irregular shapes and the arrangement of the fifth protruding portions 323 is also irregular, correspondingly, the second protruding portions 37 are also set as various irregular shapes, and the arrangement of the second protruding portions 37 is also irregular.

The specific preparation processes of the insulating layer group 3 are as follows. The first protective layer 31 and the insulating layer 32 are formed at a side of the source-drain layer 26 away from the first base substrate 1. Then, the insulating layer 32 is patterned to form a second sub-via hole 321 and form a plurality of third protruding portions 53 at a surface of the insulating layer 32 away from the first base substrate 1. At the same time, the first protective layer 31 is patterned to form a first sub-via hole 311. Then, the second protective layer 33 is formed at a side of the insulating layer 32 away from the first base substrate 1. Finally, the second protective layer 33 is patterned to form a third sub-via hole 331.

The specific preparation processes may also be as follows. The first protective layer 31 and the insulating layer 32 are formed at a side of the source-drain layer 26 away from the first base substrate 1. Then, the insulating layer 32 is patterned to form the second sub-via hole 321, and form a plurality of third protruding portions 53 at a surface of the insulating layer 32 away from the first base substrate 1. The second protective layer 33 is formed at a side of the insulating layer 32 away from the first base substrate 1. Since the second sub-via hole 321 has already been formed in the insulating layer 32, a part of the second protective layer 33 covers the hole bottom wall and the hole sidewall of the second sub-via hole 321. Finally, a patterning process is performed on the first protective layer 31 and the second protective layer 33 to form the first sub-via hole 311 and the third sub-via hole 331, and the patterning process is performed on the first protective layer 31 and the second protective layer 33 in the second sub-via hole 321. Therefore, the orthographic projection of the first sub-via hole 311 on the first base substrate 1 is located within the orthographic projection of the second sub-via hole 321 on the first base substrate 1, and the orthographic projection of the third sub-via hole 331 on the first base substrate 1 is located within the orthographic projection of the second sub-via hole 321 on the first base substrate 1. Of course, in other example implementations of the present disclosure, patterning processes (two patterning processes) may be performed on the first protective layer 31 and the second protective layer 33 separately. That is, after the second sub-via hole 321 is formed, the first protective layer 31 is patterned to form the first sub-via hole 311, and then the second protective layer 33 is formed, and finally the second protective layer 33 is patterned to form the third sub-via hole 331.

When forming the first sub-via hole 311, the second sub-via hole 321 and the third sub-via hole 331 through the same patterning process on the first protective layer 31, the insulating layer 32 and the second protective layer 33, the material of the first protective layer 31 is relatively soft, the insulating layer 32 is relatively thick, and the etching time is relatively long. The first protective layer 31 is located at the bottom, which is prone to undercut phenomenon, and the process is very difficult. Therefore, the insulating layer 32 is first patterned to form the second sub-via hole 321, and then the first protective layer 31 and the second protective layer 33 are patterned at the second sub-via hole 321 to form the first sub-via hole 311 and the third sub-via hole 331. After removing the insulating layer 32, the thickness of the first protective layer 31 and the thickness of the second protective layer 33 are both small, the etching time is relatively short, and the undercut phenomenon is not easy to occur. Thus, this can reduce the process difficulty. Moreover, the material of the insulating layer 32 may be photoresist, and when forming the third protruding portion 53 and the second sub-via hole 321 at the insulating layer 32, only exposure and development are required, and no etching is required.

It should be noted that the fourth protruding portion 322 and the fifth protruding portions 323 are formed at the insulating layer 32 by the same patterning process, and thus the height of the fourth protruding portion 322 in the third direction Z is the same as the height of the fifth protruding portions 323 in the third direction Z.

In some other example implementations of the present disclosure, the fourth protruding portion 322 and the fifth protruding portions 323 may be formed by different patterning processes, and therefore the height of the fourth protruding portion 322 in the third direction Z may be different from the height of the fifth protruding portions 323 in the third direction Z. Generally, it can be set that the height of the fourth protruding portion 322 in the third direction Z is greater than the height of the fifth protruding portions 323 in the third direction Z, so that the height of the subsequently formed first protruding portion 34 in the third direction Z is relatively large. Further, the height of a surface of the first protruding portion 34 away from the first base substrate 1 in the third direction Z may be larger than the height of a surface of the reflective layer group 5 (reflective portions 52) away from the first base substrate 1 in the third direction Z, so as to ensure that a subsequently formed first electrode 41 and a reflective portion 52 are completely disconnected at the fourth protruding portion 322.

It is also possible to set the light transmittance of the mask at the fourth protruding portion 322 and the fifth protruding portions 323 differently. Generally, it can be set so that the light transmittance at the fourth protruding portion 322 is relatively low, and the light transmittance at the fifth protruding portions 323 is relatively high, so that the height of the fourth protruding portion 322 in the third direction Z can be greater than the height of the fifth protruding portions 323 in the third direction Z. Further, the height of the surface of the first protruding portion 34 away from the first base substrate 1 in the third direction Z is larger than the height of the surface of the reflective layer group 5 (reflecting portions 52) away from the first base substrate 1 in the third direction Z, so as to ensure that a subsequently formed first electrode 41 and a reflective portion 52 are completely disconnected at the fourth protruding portion 322. Of course, it can be understood that, in a case that the photoresist used is a negative photoresist, the above light transmittance can be set to be an opposite state.

Please continue to refer to FIG. 4, a surface of the insulating layer group 3 away from the first base substrate 1 may include a first flat surface 36, and the first flat surface 36 may be located at an intersection position of a first protruding strip 341 and a second protruding strip 342. The intersection position of the first protruding strip 341 and the second protruding strip 342 is located at a corner of a pixel, which has no effect on the aperture ratio. And, a flat surface has already been formed at the intersection position of the first protruding strip 341 and the second protruding strip 342, and thus there is no need to change the process and the mask. According to the size of a spacer 6, the corner at the intersection of the first protruding strip 341 and the second protruding strip 342 may be filled to form a larger first flat surface 36 to meet the requirement of supporting the spacer 6.

The array substrate 100 may further include at least one spacer 6 arranged at a side of the first flat surface 36 away from the first base substrate 1. Because the spacer 6 is used to support the color filter substrate 200, a relatively flat support surface needs to be provided. Thus, a relatively flat base surface needs to be provided for the spacer 6. After the first flat surface 36 is provided, a relatively flat base surface is provided for the spacer 6. Accordingly, when the spacer 6 is arranged at other positions, the first flat surface 36 may also be arranged at other positions.

It should be noted that the first flat surface 36 described above is not an absolute flat surface, but may have a certain degree of roughness. The surface 36 being called a “flat surface” is in comparison with other positions of the insulation layer group 3 where protruding portions are arranged. No protruding portion is arranged at the first flat surface 36, and thus the first flat surface 36 is more planarized.

In an example implementation, please continue to refer to FIG. 4, FIG. 10 and FIG. 16 to FIG. 20, a first electrode layer 4 is arranged at a side of the insulating layer group 3 away from the first base substrate 1, so that the first electrode layer 4 is between the insulating layer group 3 and the reflective layer group 5. The first electrode layer 4 may include a plurality of first electrodes 41. A first electrode 41 is connected to a connection block 267 through a first via hole 35. The connection block 267 and a light-shielding portion 264 are designed as one piece (the connection block 267 and the light-shielding portion 264 form an integral structure). The first electrode 41 may be a pixel electrode, and the light-shielding portion 264 and a second sub-electrode 232 directly form a Cst capacitance, so as not to increase parasitic capacitance.

The material of the first electrode layer 4 may be Indium Tin Oxide (ITO). Alternatively, other transparent conductive oxides such as Indium Zinc Oxide (IZO) may also be used.

The thickness of the first electrode layer 4 is greater than or equal to 30 nm and less than or equal to 100 nm, for example, it may be 60 nm, 70 nm, 80 nm and so on. Since the thickness of the first electrode layer 4 is relatively small, a plurality of sixth protruding portions 43 are formed at a side of the first electrode layer 4 away from the first base substrate 1. The sixth protruding portions 43 are arranged as opposite to the above-mentioned second protruding portions 37. That is, the sixth protruding portions 43 are located at a side of the second protruding portions 37 away from the first base substrate 1. The height of the sidewall of a sixth protruding portion 43 in the third direction Z decreases as the distance from the center of the six protruding portion 43 on the first plane increases. For example, a surface of the sixth protruding portion 43 away from the first base substrate 1 may be set as a curved surface, and in a case where the sidewall of a second protruding portion 37 is a circular arc surface, or an ellipse arc surface, etc., correspondingly, the sidewall of the sixth protruding portion 43 is a circular arc surface, an elliptical arc surface, etc.. In a case where the second protruding portion 37 is set as a spherical cap structure, an ellipsoid cap structure, etc., correspondingly, the sixth protruding portion 43 is set as a spherical cap structure, an ellipsoid cap structure, etc. The surface of the sixth protruding portion 43 away from the first base substrate 1 may also be set as a slope. In a case where the second protruding portion 37 is set in various pyramid structures, correspondingly, the sixth protruding portion 43 is also set in various pyramid structures. When the second protruding portions 37 are arranged in various irregular shapes and the arrangement of the second protruding portions 37 is also irregular, correspondingly, the sixth protruding portions 43 are also arranged in various irregular shapes and the arrangement of the sixth protruding portions 43 is also irregular.

A seventh gap 42 is provided between two adjacent first electrodes 41. The orthographic projection of a first protruding portion 34 on the first base substrate 1 is located within the seventh gap 42 between two adjacent first electrodes 41. The orthographic projection of the first protruding portion 34 on the first base substrate 1 may coincide with the orthographic projection of the seventh gap 42 between two adjacent first electrodes 41 on the first base substrate 1, or the orthographic projection of the first protruding portion 34 on the first base substrate 1 may be located at an inner side of the orthographic projection of the seventh gap 42 between two adjacent first electrodes 41 on the first base substrate 1.

Such arrangement can make no recessed portion formed between the first electrode 41 and the first protruding strip 341, thereby further avoiding that the photoresist or the conductive material remains in the recessed portion when the first electrode 41 is formed by etching (the remaining of the photoresist or the conductive material remains in the recessed portion may cause defects of bright spots because two adjacent first electrodes 41 are conductively connected).

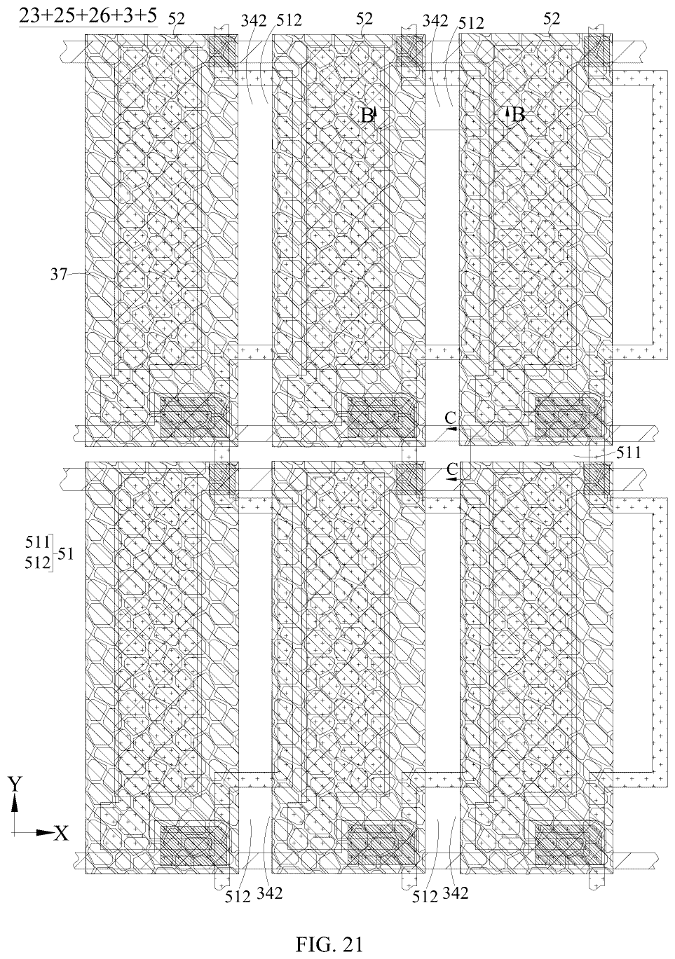

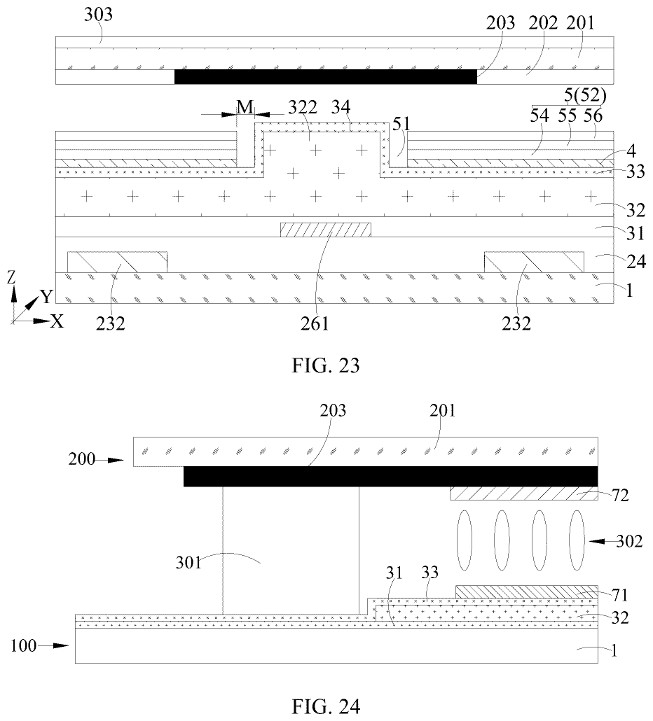

Please refer to FIG. 4, FIG. 10, FIG. 16 to FIG. 21, the reflective layer group 5 is arranged at a side of the first electrode layer 4 away from the first base substrate 1. In order to make the drawings simple and clear, a first ITO layer 54, a silver metal layer 55 and a second ITO layer 56 are not shown in FIG. 4, FIG. 10 and FIG. 16 to FIG. 20, and they are shown only in FIG. 23. Therefore, referring to FIG. 23, the reflective layer group 5 may include a first ITO layer 54, a silver metal layer 55, and a second ITO layer 56 that are stacked in sequence. Specifically, the first ITO layer 54 is arranged at a side of the insulating layer group 3 away from the first base substrate 1; the silver metal layer 55 is arranged at a side of the first ITO layer 54 away from the first base substrate 1; the second ITO layer 56 is arranged at a side of the metal layer away from the first base substrate 1.

The thickness of the first ITO layer 54 is greater than or equal to 2 nm and less than or equal to 20 nm, for example, the thickness may be 3 nm, 6 nm, 6.5 nm, 7 nm, 7.5 nm, 8 nm, 8.3 nm, 9 nm, 10 nm, 13 nm, 19 nm and so on. The thickness of the silver metal layer 55 is greater than or equal to 50 nm and less than or equal to 300 nm, for example, the thickness may be 55 nm, 60 nm, 73 nm, 80 nm, 85 nm, 90 nm, 100 nm, 110 nm, 120 nm, 180 nm, 210 nm, 260 nm and so on. The thickness of the second ITO layer 56 is greater than or equal to 1 nm and less than or equal to 10 nm, for example, the thickness may be 1.5 nm, 2.3 nm, 2.8 nm, 3 nm, 3.5 nm, 4 nm, 4.2 nm, 4.8 nm, 5.3 nm, 6.5 nm, 8 nm, 9.2 nm and so on.

The second ITO layer 56 can protect the silver metal layer 55 and prevent the silver metal layer 55 from being oxidized. Moreover, the etching rate of the first ITO layer 54 and the second ITO layer 56 is relative slow, and the etching rate of the silver metal layer 55 is relative fast, and the etching rate of the silver metal layer 55 can be balanced by the first ITO layer 54 and the second ITO layer 56, to avoid that the array substrate 100 to be etched has not been fully placed in the etching equipment but the silver metal layer 55 has been etched off. Accordingly, this can avoid the formation of an inverted triangle shaped (undercut shape) reflective portion 52 after the etching of the reflective layer group 5 is completed.

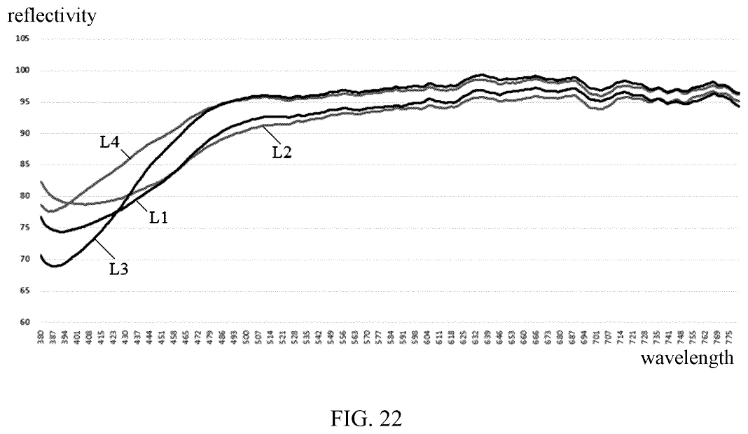

In addition, it has been determined through numerous tests that if the first electrode layer 4 is not provided, the reflectivity in the low band will be insufficient, which will lead to the phenomenon of yellowing of the display panel. Referring to FIG. 22, in this figure, L1 is the reflectivity curve when the first electrode layer 4 only covers the first via hole, L2 is the reflectivity curve when the areas of the first electrode layer 4 and the silver metal layer 55 are basically the same, L3 is the reflectivity curve when the second protective layer is not provided, and L4 is the reflectivity curve when the second protective layer is not provided and the areas of the first electrode layer 4 and the silver metal layer 55 are basically the same. As can be seen the figure: when the second protective layer is not provided and the areas of the first electrode layer 4 and the silver metal layer 55 are basically the same, the reflectivity in the entire visible light band is relatively high; when the first electrode layer 4 only covers the first via hole and when the second protective layer is not provided, the reflectivity in the low band is insufficient, resulting in yellowing phenomenon of the display panel.

Since the thickness of the reflective layer group 5 is relatively small, a plurality of third protruding portions 53 are formed at a surface of the reflective layer group 5 away from the first base substrate 1. The third protruding portions 53 are arranged opposite to the above-mentioned sixth protruding portions 43. That is, the third protruding portions 53 are located at a side of the sixth protruding portions 43 away from the first base substrate 1. The height of the sidewall of a third protruding portion 53 in the third direction Z decreases as the distance from the center of the third protruding portion 53 on the first plane increases. For example, the surface of the third protruding portion 53 away from the first base substrate 1 may be set as a curved surface, and in a case where the sidewall of a sixth protruding portion 43 is a circular arc surface or an elliptical arc surface etc., correspondingly, the sidewall of the third protruding portion 53 is a circular arc surface, or an elliptical arc surface, etc.; in a case where the sixth protruding portion 43 is set as a spherical cap structure, an ellipsoid cap structure, etc., correspondingly, the third protruding portion 53 is set as a spherical cap structure, an ellipsoid cap structure, etc. The surface of the third protruding portion 53 away from the first base substrate 1 may also be set as a slope. In a case where the sixth protruding portion 43 is set as various pyramid structures, correspondingly, the third protruding portion 53 is also set as various pyramid structures. When the sixth protruding portions 43 are arranged in various irregular shapes and the arrangement of the sixth protruding portions 43 is also irregular, correspondingly, the third protruding portions 53 are also arranged in various irregular shapes and the arrangement of the third protruding portions 53 is also irregular.

The angle between the sidewall of the third protruding portion 53 and the first plane is greater than or equal to 6° and less than or equal to 13°, for example, the angle between the sidewall of the third protruding portion 53 and the first plane may be 7.5°, 9°, 9.5°, 10°, 10.5°, 12°, etc. In this range, the reflectivity of the reflective layer group 5 is the highest.

Referring to FIG. 4, when the surface of the third protruding portion 53 away from the first base substrate 1 is set as a curved surface, the angle between the sidewall of the third protruding portion 53 and the first plane refers to an angle λ between the first plane and a tangent line at an end of the third protruding portion 53 close to the first base substrate 1.

The orthographic projection of a first electrode 41 on the first base substrate 1 may overlap with the orthographic projection of a reflective portion 52 on the first base substrate 1. For example, the orthographic projection of the first electrode 41 on the first base substrate 1 may coincide with the orthographic projection of the reflective portion 52 on the first base substrate 1; or, an edge of the orthographic projection of the first electrode 41 on the first base substrate 1 is located within an edge of the orthographic projection of the reflective portion 52 on the first base substrate 1, and there is a gap between the edge of the orthographic projection of the first electrode 41 on the first base substrate 1 and the edge of the reflective portion 52 on the first base substrate 1. The width of the gap is greater than or equal to 1 micron and less than or equal to 5 microns, for example, the width of the gap may be 2 microns, 3 microns, 4.5 microns and so on. Such an arrangement can avoid errors in the preparation process of the first electrode 41 and the reflective portion 52 (such errors may cause that the reflective portion 52 does not cover the first electrode 41).

In addition, in some other example implementations of the present disclosure, the orthographic projection of the reflective portion 52 on the first base substrate 1 may be located within the orthographic projection of the first electrode 41 on the first base substrate 1. That is, the edge of the first electrode 41 is not covered by the reflective portion 52. Because the material of the first electrode 41 includes ITO, the first electrode 41 is easily to be crystallized when the temperature rises during the process of deposition of the first electrode 41. After the first electrode 41 is etched, some residues will form residual sand. If the reflective portion 52 covers the etched position of the first electrode 41, due to the presence of residual sand, the reflective layer group 5 is likely to form a bulge at the residual sand, resulting in abnormal reflectivity and abnormal display. If the edge of the first electrode 41 is not covered by the reflective portion 52, the reflective portion 52 will not cover the residual sand, and thus bulges and abnormal reflectivity due to the residual sand will not occur. Accordingly, the display panel can display normally.

Referring to FIG. 10, FIG. 16 to FIG. 21, the orthographic projection of a second sub-electrode on the first base substrate 1 is located within the orthographic projection of the first electrode 41 on the first base substrate 1, and the orthographic projection of the first electrode 41 on the first base substrate 1 overlaps with the orthographic projection of a gate line 231 on the first base substrate 1. That is, the first electrode 41 not only covers the second sub-electrode, but also the first electrode 41 protrudes towards a side of the gate line 231 to overlap with a part of the gate line 231.

The orthographic projection of the second sub-electrode on the first base substrate 1 is located within the orthographic projection of the reflective portion 52 on the first base substrate 1, and the orthographic projection of the reflective portion 52 on the first base substrate 1 overlaps with the orthographic projection of the gate line 231 on the first base substrate 1. That is, the reflective portion 52 not only covers the second sub-electrode, but also protrudes towards a side of the gate line 231 to overlap with a part of the gate line 231. The area of the reflective portion 52 is made as large as possible to increase the reflective area, thereby increasing the reflectivity and further improving the display effect.

The orthographic projection of the first electrode 41 on the first base substrate 1 overlaps with the orthographic projection of a data line 261 on the first base substrate 1. That is, the first electrode 41 not only covers the second sub-electrode, but also the first electrode 41 protrudes towards a side of the data line 261 to overlap with a part of the data line 261. The orthographic projection of the reflective portion 52 on the first base substrate 1 overlaps with the orthographic projection of the data line 261 on the first base substrate 1. That is, the reflective portion 52 not only covers the second sub-electrode, but also protrudes towards a side of the data line 261 to overlap with a part of the data line 261. The area of the reflective portion 52 is made as large as possible to increase the reflective area, thereby increasing the reflectivity and further improving the display effect.

A first gap 51 is provided between two adjacent reflective portions 52, and a seventh gap 42 is provided between two adjacent first electrodes 41. The orthographic projection of the first gap 51 on the first base substrate 1 may overlap with the orthographic projection of the seventh gap 42 on the first base substrate 1. The first gap 51 may include a plurality of first sub-gaps 511 and a plurality of second sub-gaps 512. The first sub-gaps 511 extend along the first direction X. The second sub-gaps 512 extend along the second direction Y. The plurality of first sub-gaps 51 and the plurality of second sub-gaps 512 are connected to form a grid-shaped first gap 51.

Referring to FIG. 10, and FIG. 16 to FIG. 21, a first protruding portion 34 is provided in the first gap 51. The width of the first gap 51 is equal to the width of the first protruding portion 34. That is, the orthographic projection of the first protruding portion 34 on the base substrate 1 overlaps with the orthographic projection of the first gap 51 on the first base substrate 1. That is to say, the first protruding portion 34 fills the first gap 51 in the width direction of the first gap 51.

Specifically, a first protruding strip 341 is arranged in a first sub-gap 511. The width of the first protruding strip 341 may be equal to the width of the first sub-gap 511. A second protruding strip 342 is arranged in a second sub-gap 512. The width of the second protruding strip 342 may be equal to the width of the second sub-gap 512.

With such an arrangement, no recessed portion is formed between the reflective portion 52 and the first protruding strip 341, thereby further preventing photoresist or conductive material from remaining in the recessed portion when the reflective portion 52 is formed by etching (remaining of the photoresist or conductive material in the recessed portion may result in that two adjacent reflective portions 52 are conductively connected to cause defects of bright spots).

Of course, in some other example implementations of the present disclosure, as shown in FIG. 23, due to limitations of process conditions (alignment accuracy of the exposure machine), the width of the first gap 51 may be greater than the width of the first protruding portion 34. Specifically, the width of the first protruding strip 341 may be smaller than the width of the first sub-gap 511, and the width of the second protruding strip 342 may be smaller than the width of the second sub-gap 512. The distance M between sidewalls of the first protruding portion 34 and the first gap 51 may be greater than or equal to 1.2 μm.

In some other example implementations of the present disclosure, as shown in FIG. 12, the width K1 of the first gap 51 may be smaller than the width of the first protruding portion 34. In this case, a part of the first protruding portion 34 may extend to a side of the reflective portion 52 close to the first base substrate 1. For example, a reflective portion 52 at a side of the first protruding portion 34 may extend to a half-slope position of a slope of the first protruding portion, and a reflective portion 52 at an opposite side of first protruding portion 34 does not extend to the side of the first protruding portion 34 away from the first base substrate 1; or, the reflective portions 52 at both sides of the first protruding portion 34 all extend to half-slope positions of the slope of the first protruding portion 34. Since the reflective layer group 5 is directly arranged at the side of the first electrode 41 away from the first base substrate 1 and the material of the reflective layer group 5 is conductive, after electricity is applied to the first electrode 41, the electricity is also applied to the reflective layer group 5. After the first protruding portion 34 is provided, the surface of the first protruding portion 34 on which the reflective material layer is formed is relatively smooth. When forming different reflective portions 52 of different pixels by etching the reflective material layer, the photoresist on the first protruding portion 34 is easy to remove, and the reflective material layer will also be etched away, so that there is a first gap 51 between two adjacent reflective portions 52. In this way, pixel electrodes of two adjacent sub-pixels will not be connected to each other, and defects of bright spots will not occur.

Referring to FIG. 23, in some other example implementations of the present disclosure, the second protruding portions 37 may not be provided at the insulating layer group 3, and therefore, the sixth protruding portions 43 will not be formed at the first electrode 41, and the third protruding portions 53 may not be formed at the reflective portions 52. In this case, the height of the first protruding portion 34 away from the first base substrate 1 in the third direction Z may be larger than the height of the surface of the reflective layer group 5 (reflective portions 52) away from the first base substrate 1 in the third direction Z, so as to ensure that a subsequently formed first electrode 41 and a reflective portion 52 are completely disconnected at the first protruding portion 34. In this way, pixel electrodes of two adjacent sub-pixels are not connected to each other, and defects of bright spots will not occur.

Based on the same inventive concept, an example implementation of the present disclosure provides a display panel. As shown in FIG. 23 and FIG. 24, the display panel may include an array substrate 100, a color filter substrate 200, a sealant frame 301 and a liquid crystal layer 302. The array substrate 100 is the array substrate 100 described in any one of the above implementations. The color filter substrate 200 is arranged at a side of the array substrate 100 close to the reflective layer 5. The sealant frame 301 is arranged between the array substrate 100 and the color filter substrate 200. The liquid crystal layer 302 is arranged between the array substrate 100 and the color filter substrate 200 and is located within the sealant frame 301.

The specific structure of the array substrate 100 has been described above in detail, and therefore, repeated descriptions will be omitted here.

Referring to FIG. 23, when the third protruding portions 53 are not provided at the reflective portions 52, the display panel may further include a diffusion film 303 arranged at a side of the color filter substrate 200 away from the array substrate 100. Diffuse reflection is realized by the diffusion film 303 (POL), so that it is not needed to provide the third protruding portions 53 at the reflective portions 52.

Referring to FIG. 24, a first alignment film 71 is provided at a side of the array substrate 100 close to the color filter substrate 200, and a second alignment film 72 is provided at a side of the color filter substrate 200 close to the array substrate 100.

In an example implementation, the color filter substrate 200 may include a second base substrate 201, a light-transmitting portion 202 and a light-blocking portion 203. The light-transmitting portion 202 is arranged at a side of the second base substrate 201 close to the array substrate 100. The light-transmitting portion 202 is arranged opposite to a pixel region. The light-blocking portion 203 is arranged at a side of the second base substrate 201 close to the array substrate 100. The light-blocking portion 203 is arranged opposite to a gap between pixel regions. The orthographic projection of the light-blocking portion 203 on the second base substrate 201 is located within the second base substrate, that is, an edge of the light-blocking portion 203 is not flush with an edge of the second base substrate 201, but is retracted relative to the edge of the second base substrate 201.

In addition, after many tests and verifications, 5˜50% of defects of bright spots occur in the display panel of related art, and after 7 days of the reliability (HTO) test, ⅙ of the new defects of bright spots are added.

The display panel according to embodiments of the present disclosure has no defect of bright spots, and after 20 days of the reliability (HTO) test, there is still no defects of bright spots.

Based on the same inventive concept, an example implementation of the present disclosure provides a display device. The display device may include the display panel described in any one of the above implementations. The specific structure of the display panel has been described in detail above, and thus repeated descriptions will be omitted here.

The specific type of the display device is not particularly limited, and any type of display device commonly used in this field can be used, such as a mobile device like a mobile phone, a wearable device like a watch, etc., and those skilled in the art can perform corresponding selections according to the specific use of the display device, and detailed descriptions are not provided here.

It should be noted that, in addition to the display panel, the display device may further include other necessary members and components. Taking a display as an example, the display may further include, for example, a casing, a circuit board, a power cord, etc., and those skilled in the art can correspondingly add other members or components according to specific usage requirements of the display device, and detailed descriptions will not be provided here.

Compared with the related art, the beneficial effects of the display device provided by the example implementations of the present invention are the same as that of the array substrate 100 provided by the above example implementation, and will not be repeated here.

Other implementations of the present disclosure will be readily apparent to those skilled in the art from consideration of the specification and practice of the invention disclosed herein. The present disclosure is intended to cover any modification, use or adaptation of the present disclosure, and these modifications, uses or adaptations follow the general principles of the present disclosure and include common knowledge or conventional technical means in the technical field not disclosed in the present disclosure. The specification and examples are to be considered exemplary only.

1. An array substrate, comprising:
a first base substrate;
an insulating layer group arranged at a side of the first base substrate, wherein a surface of the insulating layer group away from the first base substrate is provided with a first protruding portion; and
a reflective layer group arranged at a side of the insulating layer group away from the first base substrate, wherein the reflective layer group comprises a plurality of reflective portions, a first gap is provided between two adjacent reflective portions, and the first protruding portion is arranged in the first gap.

2. The array substrate according to claim 1, wherein a width of the first gap is less than or equal to a width of the first protruding portion, and a part of the first protruding portion extends to a side of the reflective portions close to the first base substrate.

3. The array substrate according to claim 1, wherein the first protruding portion comprises:
a plurality of first protruding strips extending along a first direction;
a plurality of second protruding strips extending along a second direction, wherein the plurality of first protruding strips are connected with the plurality of second protruding strips to form a plurality of grids;
wherein first gap comprises:
a plurality of first sub-gaps extending along the first direction, wherein the first protruding strips are arranged in the first sub-gaps; and
a plurality of second sub-gaps extending along the second direction, wherein the second protruding strips are arranged in the second sub-gaps, and the plurality of first sub-gaps are connected with the plurality of second sub-gaps to form a plurality of grids;
wherein the first direction and the second direction are parallel to a surface of the first base substrate close to the insulating layer group, and the first direction intersects the second direction.

4. The array substrate according to claim 3, wherein one of the first protruding strips at least comprises a first part and a second part, and a width of the first part in the second direction is different from a width of the second part in the second direction;
wherein one of the second protruding strips at least comprises a third part and a fourth part, and a width of the third part in the first direction is different from a width of the fourth part in the first direction.

5. The array substrate according to claim 3, further comprising:
a switch layer group arranged between the first base substrate and the insulating layer group, wherein the switch layer group comprises a plurality of switch units, a second gap is provided between two adjacent switch units, and an orthographic projection of the first protruding portion on the first base substrate is located within an orthographic projection of the second gap on the first base substrate.

6. The array substrate according to claim 5, wherein the switch layer group further comprises:
a plurality of gate lines extending along the first direction, wherein one of the gate lines is correspondingly located between two adjacent switch units, and orthographic projections of the first protruding strips on the first base substrate overlap with orthographic projections of the gate lines on the first base substrate; and
a plurality of data lines extending along the second direction, wherein one of the data lines is correspondingly located between two adjacent switch units, and orthographic projections of the second protruding strips on the first base substrate overlap with orthographic projections of the data lines on the first base substrate.

7. The array substrate according to claim 6, wherein the first protruding strips have a width in the second direction greater than or equal to that of the gate lines in the second direction, and the second protruding strips have a width in the first direction greater than or equal to that of the data lines in the first direction.

8. The array substrate according to claim 5, wherein the switch layer group further comprises:
a gate layer arranged at a side of the first base substrate;
a gate insulating layer arranged at a side of the gate layer away from the first base substrate;
an active layer arranged at a side of the gate insulating layer away from the first base substrate; and
a source-drain layer arranged at a side of the active layer away from the first base substrate;
wherein the gate layer comprises:
a plurality of gate lines extending along the first direction;
a plurality of second sub-electrodes arranged in an array at a side of the first base substrate; and
a plurality of connection portions, wherein one of the connection portions is connected between two adjacent second sub-electrodes which are arranged along the first direction.

9. (canceled)

10. The array substrate according to claim 8, wherein a third gap is provided between one of second sub-electrodes and one of the gate lines, the one of second sub-electrodes and the one of the gate lines belong to different adjacent pixels, and an orthographic projection of one of the first protruding strips on the first base substrate overlaps with an orthographic projection of the third gap on the first base substrate, and the first protruding strip has a width in the second direction smaller than a width of the third gap in the second direction.

11. The array substrate according to claim 8, wherein the active layer comprises:
a channel portion arranged at a side of the gate lines away from the first base substrate; and
a filling portion spaced apart from the channel portion, located at a side of the connection portions away from the first base substrate, and covering at least part of sidewalls of the connection portions.

12. The array substrate according to claim 11, wherein the source-drain layer comprises:
a plurality of data lines extending along the second direction, wherein a part of one of the data lines is located at a side of the filling portion away from the connection portions;
a plurality of light-shielding portions arranged in an array, wherein orthographic projections of the light-shielding portions on the first base substrate are located within orthographic projections of the second sub-electrodes on the first base substrate;
a source electrode, wherein one end of the source electrode is connected to one of the data lines; and
a drain electrode, wherein one end of the drain electrode is connected to one of the light-shielding portions.

13. The array substrate according to claim 12, wherein one of the data lines comprises:
a plurality of first segments extending along the first direction;
a plurality of second segments extending along the second direction and connected to a part of the first segments, wherein one of the second segments is connected to ends of two adjacent first segments; and
a plurality of third segments extending along the second direction and connected to the another part of the first segments, wherein one of the third segments is connected to other ends of two adjacent first segments, and the second segments and the third segments are arranged alternately;
wherein one of the third segments is located between two adjacent light-shielding portions, and is at different distances from the two adjacent light-shielding portions, and one of the second sections is connected to two pixels which are adjacent in the second direction.

14. The array substrate according to claim 13, wherein a width of a fifth gap between the one of the third segments and a first light-shielding portion is larger than a width of a fourth gap between the one of the third segments and a second light-shielding portion, the first light-shielding portion and the one of the third segments belong to a same pixel, and the second light-shielding portion and the one of the third segments belong to different adjacent pixels;
wherein the orthographic projection of one of the second protruding strips on the base substrate overlaps with an orthographic projection of the fifth gap on the base substrate, and a width of the second protruding strip in the first direction smaller than a width of the fifth gap in the first direction.

15. (canceled)

16. The array substrate according to claim 8, wherein a first via hole is provided in the insulating layer group, and the array substrate further comprises:
a first electrode layer arranged between the insulating layer group and the reflective layer, wherein the first electrode layer comprises a plurality of first electrodes, and one of the first electrodes is connected with the source-drain layer through the first via hole;
wherein orthographic projections of the first electrodes on the first base substrate overlap with orthographic projections of the reflective portions on the first base substrate.

17. (canceled)

18. The array substrate according to claim 1, wherein the reflective layer group comprises:
a first Indium Tin Oxide (ITO) layer arranged at a side of the insulating layer group away from the first base substrate;
a silver metal layer arranged at a side of the first ITO layer away from the first base substrate; and
a second ITO layer arranged at a side of the silver metal layer away from the first base substrate.

19. The array substrate according to claim 1, wherein a height of a surface of the first protruding portion away from the first base substrate in a third direction is higher than a height of a surface of the reflective layer group away from the first base substrate in the third direction, and the third direction is perpendicular to a surface of the first base substrate close to the insulating layer group.

20. The array substrate according to claim 1, wherein a plurality of second protruding portions are provided at a surface of the insulating layer group away from the first base substrate, a plurality of third protruding portions are provided at a surface of the reflective layer group away from the first base substrate, and orthographic projections of the second protruding portions on the first base substrate are located within orthographic projections of the third protruding portions on the first base substrate.

21. The array substrate according to claim 20, wherein a height of the second protruding portions is the same as a height of the first protruding portion.

22. The array substrate according to claim 20, wherein the insulating layer group comprises:
a first protective layer arranged at a side of the first base substrate; and
an insulating layer arranged at a side of the first protective layer away from the first base substrate;
wherein the first protruding portion and the second protruding portions are provided at the insulating layer;
wherein the insulating layer group further comprises:
a second protective layer arranged at a side of the insulating layer away from the first base substrate, a fourth protruding portion and a plurality of fifth protruding portions are arranged at the insulating layer, and the first protruding portion corresponding to the fourth protruding portion and the second protruding portions corresponding to the fifth protruding portions are provided at the second protective layer.

23-24. (canceled)

25. A display panel, comprising:
an array substrate, comprising:
a first base substrate;
an insulating layer group arranged at a side of the first base substrate, wherein a surface of the insulating layer group away from the first base substrate is provided with a first protruding portion; and
a reflective layer group arranged at a side of the insulating layer group away from the first base substrate, wherein the reflective layer group comprises a plurality of reflective portions, a first gap is provided between two adjacent reflective portions, and the first protruding portion is arranged in the first gap;
a color filter substrate arranged at a side of the array substrate close to the reflective layer group;
a sealant frame arranged between the array substrate and the color filter substrate; and
a liquid crystal layer arranged between the array substrate and the color filter substrate and located in the sealant frame.

26-27. (canceled)
